(19) United States
(12) Patent Application Publication
(10) Pub. No.: US 2026/0247776 A1
(43) Pub. Date: Aug. 20, 2026

(54) DISPLAY DEVICE, METHOD FOR MANUFACTURING THE SAME AND ELECTRONIC DEVICE

(71) Applicant: Samsung Display Co., Ltd., Yongin-si (KR)

(72) Inventors: Jin Seok PARK, Yongin-si (KR); Moon Jung AN, Yongin-si (KR); Hye Lim KANG, Yongin-si (KR)

(21) Appl. No.: 19/442,058

(22) Filed: Jan. 7, 2026

(30) Foreign Application Priority Data
Feb. 17, 2025 (KR) 10-2025-0020183

(51) Int. Cl. H10H 29/49; H10H 20/01; H10H 20/831; H10H 29/01; H10H 29/03

(52) U.S. Cl. CPC H10H 29/49; H10H 20/032; H10H 20/831; H10H 29/012; H10H 29/03

(57) ABSTRACT

A display device, a method for manufacturing the same, and an electronic device are provided. The display device includes a substrate, a pixel electrode and a common electrode spaced apart from each other on the substrate, a first organic layer covering at least a portion of the pixel electrode and the common electrode and a light emitting element arranged on the first organic layer, the light emitting element including an element planarization layer, a plurality of semiconductor layers, a first contact electrode, and a second contact electrode, wherein the element planarization layer covers one surface of the first contact electrode and the second contact electrode, and planarizes a step caused by the first contact electrode and the second contact electrode, wherein the first organic layer covers one surface and a side surface of the element planarization layer.

### CROSS-REFERENCE TO RELATED APPLICATION

The present application claims priority to and the benefit of Korean Patent Application No. 10-2025-0020183, filed on February 17, 2025, in the Korean Intellectual Property Office, the entire disclosure of which is incorporated herein by reference .

### BACKGROUND

### 1. Field

One or more aspects of embodiments of the present disclosure relate to a display device, a method for manufacturing the same, and an electronic device.

### 2. Description of the Related Art

As the production, transmission and manipulation of information gains economical, cultural, and social importance, the demand for display devices in one or more suitable forms for displaying images is increasing. The display device may be a flat panel display device such as a liquid crystal display, a field emission display, a light emitting display, and/or the like.

The light emitting display device may include an organic light emitting display device including an organic light emitting diode element as a light emitting element, and/or an ultra-small light emitting display device including a micro light emitting diode element (hereinafter referred to as a micro light emitting element) as a light emitting element. Because the micro light emitting diode element is made of an inorganic material, it has the advantage of having a suitably long lifespan due to less deterioration issues compared to an organic light emitting diode element.

### SUMMARY

One or more aspects and features of embodiments of the present disclosure are to provide a display device and a method of manufacturing the same capable of minimizing or reducing the tilting of a light emitting element during a transfer process of the light emitting element.

However, aspects of the present disclosure are not restricted to the ones set forth herein. The above and other aspects of the present disclosure will become more apparent to one of ordinary skill in the art to which the present disclosure pertains by referencing the detailed description of the present disclosure given herein below.

According to one or more embodiments of the present disclosure, a display device includes a substrate, a pixel electrode and a common electrode spaced apart from each other on the substrate, a first organic layer covering at least a portion of the pixel electrode and the common electrode, and a light emitting element arranged on the first organic layer, the light emitting element including an element planarization layer, a plurality of semiconductor layers, a first contact electrode, and a second contact electrode, wherein the element planarization layer covers one surface of the first contact electrode and the second contact electrode, and planarizes or reduces a step caused by the first contact electrode and the second contact electrode, wherein the first organic layer covers one surface and a side surface of the element planarization layer.

The first contact electrode and the second contact electrode may be respectively arranged on one side and a side surface of the light emitting element and may be spaced apart from a top surface of the light emitting element.

The display device further may include a first connection electrode connecting the pixel electrode and the first contact electrode, and a second connection electrode connecting the common electrode and the second contact electrode.

The first contact electrode may be in direct contact with the first connection electrode at a side surface of the plurality of semiconductor layers, and the second

contact electrode may be in direct contact with the second connection electrode at a side surface of the plurality of semiconductor layers.

The light emitting element may further include, a conductive layer arranged on the element planarization layer and a protective film arranged on one surface and side surfaces of the conductive layer and side surfaces of the plurality of semiconductor layers, wherein the first contact electrode may be arranged on the protective film and may be connected to the conductive layer exposed without being covered by the protective film, wherein the second contact electrode may be arranged on the protective film and may be arranged in a hole penetrating the conductive layer and a portion of the plurality of semiconductor layers.

The element planarization layer may be filled in the hole.

The element planarization layer may be made of an insulating organic material.

The element planarization layer may cover entire surface of one surface on which the first contact electrode and the second contact electrode are arranged.

The side surface of the element planarization layer may be aligned with the side surface of each of the first contact electrode and the second contact electrode.

The side surface of the element planarization layer may protrude further than the side surfaces of the first contact electrode and the second contact electrode.

The element planarization layer may not be arranged between the first contact electrode and the second contact electrode.

The first organic layer may be in contact with one surface of the protective film between the first contact electrode and the second contact electrode.

The light emitting element may be divided into a first element rod having a first inclination angle on a side surface, and a second element rod arranged on the first element rod and having a second inclination angle on the side surface, wherein the second inclination angle is smaller than the first inclination angle.

The first element rod may include the conductive layer, a first semiconductor layer, and an active layer, wherein the first contact electrode and the second contact electrode may be arranged on a side surface of the first element rod.

According to one or more embodiments of the present disclosure, a method for manufacturing a display device includes forming an element planarization layer on one surface of a light emitting element arranged on a first substrate, forming an organic layer covering at least a portion of a pixel electrode and a common electrode arranged on a second substrate, aligning the element planarization layer facing the organic layer in each of the light emitting elements, and then transferring the light emitting elements onto the organic layer and forming a first connection electrode connecting a first contact electrode of the light emitting element to the pixel electrode and a second connection electrode connecting a second contact electrode of the light emitting element to the common electrode.

The forming the element planarization layer may include, preparing a light emitting element having the first contact electrode and the second contact electrode spaced apart from each other on one side, preparing a first relay substrate having an organic layer having adhesion arranged on a top surface of the first relay substrate, transferring the light emitting element onto the organic layer and removing the first relay substrate and dry etching the organic layer to remove the organic layer arranged on the side of the light emitting element, thereby forming the element planarization layer on one side of the light emitting element.

In the transferring the light emitting elements onto the organic layer, a portion of a side surface of the first contact electrode and a portion of a side surface of the second contact electrode of the light emitting elements may be embedded in the organic layer, and a remaining portion of the side surface of the first contact electrode and a remaining portion of the side surface of the second contact electrode may not be covered by the organic layer.

The first connection electrode may be connected to a remaining portion of the side surface of the first contact electrode, and the second connection electrode may be connected to a remaining portion of the side surface of the second contact electrode.

An electronic device includes a display panel, a window arranged on the display panel and a bottom cover arranged below the display panel, wherein the display panel includes: a substrate, a pixel electrode and a common electrode spaced apart from each other on the substrate, a first organic layer covering at least a portion of the pixel electrode and the common electrode and a light emitting element arranged on the first organic layer, the light emitting element including an element planarization layer, a plurality of semiconductor layers, a first contact electrode, and a second contact electrode, wherein the element planarization layer covers one surface of the first contact electrode and the second contact electrode, and planarizes or reduces a step caused by the first contact electrode and the second contact electrode, wherein the first organic layer covers one surface and a side surface of the element planarization layer.

The electronic device may further include a battery arranged in a space of the bottom cover and supplying power to the display device and a middle frame arranged between the window and the bottom cover.

According to one or more embodiments, a display device and a manufacturing method thereof may minimize or reduce tilting of a light emitting element during a transfer process of the light emitting element. Accordingly, the possibility of causing a dark spot when the display panel is illuminated may be reduced and the reliability of the panel may be improved by minimizing or reducing the miscontact between the contact electrode and the connection electrode of the light emitting element.

However, the effects, aspects, and features of the present disclosure are not limited to the aforementioned effects, aspects, and features, and one or more suitable other effects, aspects, and features are included in the present specification.

### BRIEF DESCRIPTION OF THE DRAWINGS

These and/or other aspects will become apparent and more readily appreciated from the following description of the embodiments, taken in conjunction with the accompanying drawings in which:

FIG. 1 is a perspective view illustrating a display device according to one or more embodiments.

FIG. 2 is a layout drawing illustrating a display device according to one or more embodiments.

FIG. 3 is a block drawing illustrating a display device according to one or more embodiments.

FIG. 4 is an equivalent circuit drawing illustrating a sub-pixel according to one or more embodiments.

FIG. 5 is a layout diagram illustrating pixels of a display area according to one or more embodiments.

FIG. 6 is a cross-sectional view illustrating an example cross-section of a display panel corresponding to lines I-I' in FIG. 5.

FIG. 7 is a cross-sectional view illustrating an example of area A in FIG. 6 in more detail.

FIG. 8 is a cross-sectional view illustrating another example of area A of FIG. 6 in more detail.

FIG. 9 is a cross-sectional view illustrating another example of the cross-section of the display panel corresponding to the line I-I’ of FIG. 5.

FIG. 10 is a cross-sectional view illustrating an example of area B of FIG. 9 in more detail.

FIG. 11 is a cross-sectional view illustrating another example of area B of FIG. 9 in more detail.

FIG. 12 is a cross-sectional view illustrating another example of area B of FIG. 9 in more detail.

FIG. 13 is a cross-sectional view illustrating another example of area B of FIG. 9 in more detail.

FIG. 14 is a drawing to illustrate an example in which a comparable (e.g., prior art) light emitting element is adhered to the first organic layer without being parallel to the left and right.

FIG. 15 is a flowchart illustrating a method for manufacturing a display device according to one or more embodiments.

FIGS. 16-24 are example drawings to illustrate a method for manufacturing a display device according to one or more embodiments.

FIGS. 25 and 26 are each an example drawing illustrating a smart watch including a display device according to one or more embodiments.

FIG. 27 is an exploded perspective view of a smart watch including a display device according to one or more embodiments.

FIGS. 28 is an example views of a virtual reality (VR) device including a display device according to one or more embodiments.

FIG. 29 is an example view of a VR device including a display device according to one or more embodiments.

FIG. 30 is an example view illustrating a vehicle instrument cluster and center fascia including display devices according to one or more embodiments.

FIG. 31 is an example view of a transparent display device including a display device according to one or more embodiments.

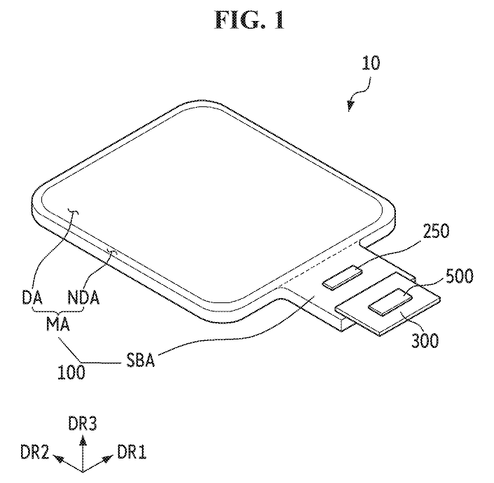

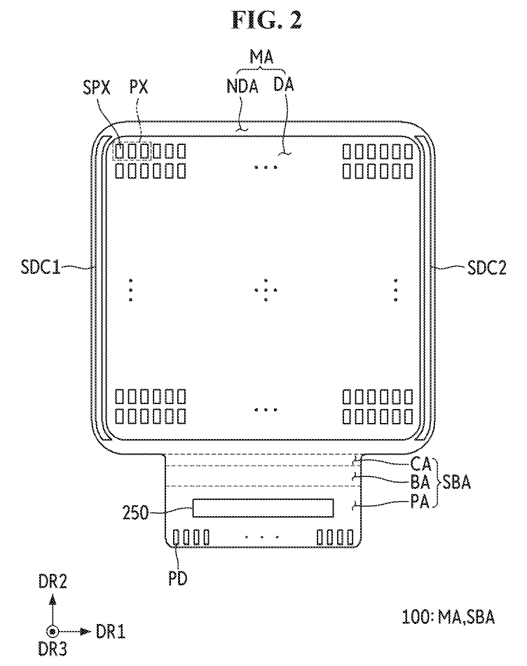

### DETAILED DESCRIPTION

Aspects and features of embodiments of the disclosure and methods of accomplishing the same may be understood more readily by reference to the detailed description of embodiments and the accompanying drawings. Hereinafter, aspects of some embodiments will be described in more detail with reference to the accompanying drawings. The described embodiments, however, may be embodied in various different forms, and should not be construed as being limited to only the illustrated embodiments herein. Rather, these embodiments are provided as examples so that the disclosure will be thorough and complete, and will fully convey the aspects and features of the disclosure to those skilled in the art. Accordingly, processes, elements, and techniques that are not necessary to those having ordinary skill in the art for a complete understanding of the aspects and features of the disclosure might not be described.

Unless otherwise noted, like reference numerals, characters, or combinations thereof denote like elements throughout the attached drawings and the written description, and thus, duplicative descriptions thereof will not be provided. Further, parts not related to the description of one or more embodiments might not be shown to make the description clear and concise.

In the drawings, the relative sizes of elements, layers, and regions may be exaggerated for clarity. Additionally, the use of cross-hatching and/or shading in the accompanying drawings is generally provided to clarify boundaries between adjacent elements. As such, neither the presence nor the absence of cross-hatching and/or shading conveys or indicates any preference or requirement for particular materials, material properties, dimensions, proportions, commonalities between illustrated elements, and/or any other characteristic, attribute, property, and/or the like, of the elements, unless specified.

Various embodiments are described herein with reference to sectional illustrations that are schematic illustrations of embodiments and/or intermediate structures. As such, variations from the shapes of the illustrations as a result, for example, of manufacturing techniques and/or tolerances, are to be expected. Further, specific structural and/or functional descriptions disclosed herein are merely illustrative for the purpose of describing embodiments according to the disclosure. Thus, embodiments disclosed herein should not be construed as limited to the particular illustrated shapes of regions, but are to include deviations in shapes that result from, for instance, manufacturing.

For example, an implanted (e.g., inserted and/or recessed) region illustrated as a rectangle may have rounded or curved features and/or a gradient of implant concentration at its edges rather than a binary change from implanted to non-implanted region. Likewise, a buried region formed by implantation may result in some implantation in the region between the buried region and the surface through which the implantation takes place. Thus, the regions illustrated in the drawings are schematic in nature and their shapes are not intended to illustrate the actual shape of a region of a device and are not intended to be limiting. Additionally, as those skilled in the art would realize, the described embodiments may be modified in one or more suitable different ways, all without departing from the spirit and/or scope of the disclosure.

In the detailed description, for the purposes of explanation, numerous specific details are set forth to provide a thorough understanding of one or more embodiments. It is apparent, however, that one or more embodiments may be practiced without these specific details or with one or more equivalent arrangements. In other instances, well-known or easily understood structures and devices are shown in block diagram form to avoid unnecessarily obscuring of one or more suitable embodiments.

Spatially relative terms, such as “beneath,” “below,” “lower,” “under,” “above,” “upper,” and/or the like, may be used herein for ease of explanation to describe one element, aspect, or feature’s relationship to another element(s), aspect(s), or feature(s) as illustrated in the drawings. It will be understood that the spatially relative terms are intended to encompass different orientations of the device in use or in operation, in addition to the orientation depicted in the drawings. For example, if the device in the drawings is turned over, elements described as “below” or “beneath” or “under” other elements or features would then be oriented “above” the other elements or features. Thus, the example terms “below” and “under” can encompass both (e.g., simultaneously) an orientation of above and below. The device may be otherwise oriented (e.g., rotated 90 degrees or at other orientations) and the spatially relative descriptors used herein should be interpreted accordingly. Similarly, when a first part is described as being arranged “on” a second part, this indicates that the first part is arranged at an upper side or a lower side of the second part without the limitation to the upper side thereof on the basis of the gravity direction.

Further, in this specification, the phrase “on a plane,” or “in a plan view,” refers to viewing a target portion from the top, and the phrase “on a cross-section” refers to viewing a cross-section formed by vertically cutting a target portion from the side.

It will be understood that when an element, layer, region, or component is referred to as being “formed on,” “on,” “connected to,” or “coupled to” another element, layer, region, or component, it can be directly formed on, on, connected to, or coupled to the other element, layer, region, or component, or indirectly formed on, on, connected to, or coupled to the other element, layer, region, or component such that one or more intervening elements, layers, regions, or components may be present. For example, when a layer, region, or component is referred to as being “electrically connected” or “electrically coupled” to another layer, region, or component, it can be directly electrically connected or coupled to the other layer, region, and/or component or intervening layers, regions, or components may be present. However, “directly connected/directly coupled” refers to one component directly connecting or coupling another component without an intermediate component. In one or more embodiments, other expressions describing relationships between components such as “between,” “immediately between” or “adjacent to” and “directly adjacent to” may be construed similarly. In one or more embodiments, it will also be understood that when an element or layer is referred to as being “between” two elements or layers, it can be the only element or layer between the two elements or layers, or one or more intervening elements or layers may also be present.

For the purposes of the disclosure, expressions such as “at least one of,” “one of,” and “selected from among,” when preceding a list of elements, modify the entire list of elements and do not modify the individual elements of the list. For example, “at least one selected from among X, Y, and Z,” “at least one of X, Y, or Z,” and “at least one selected from the group consisting of X, Y, and Z” may be construed as X only, Y only, Z only, any combination of two or more of X, Y, and Z, such as, for instance, XYZ, XYY, XZ, YZ, and ZZ, or any variation thereof. Similarly, the expression such as “at least one of A and/or B” may include A, B, or A and B. As used herein, the term “and/or” includes any and all combinations of one or more of the associated listed items. For example, the expression such as “A and/or B” may include A, B, or A and B. Further, the use of “may” when describing embodiments of the disclosure refers to “one or more embodiments of the disclosure”.

It will be understood that, although the terms “first,” “second,” “third,” and/or the like, may be used herein to describe various elements, components, regions, layers and/or sections, these elements, components, regions, layers and/or sections should not be limited by these terms. These terms are used to distinguish one element, component, region, layer or section from another element, component, region, layer or section. Thus, a first element, component, region, layer or section described herein below could be termed a second element, component, region, layer or section, without departing from the spirit and scope of the disclosure.

In the examples, the x-axis, the y-axis, and/or the z-axis are not limited to three axes of a rectangular coordinate system, and may be interpreted in a broader sense. For example, the x-axis, the y-axis, and the z-axis may be perpendicular to one another, or may represent different directions that are not perpendicular to one another. The same applies for first, second, and/or third directions.

The terminology used herein is for the purpose of describing particular embodiments only and is not intended to be limiting of the disclosure. As used herein, the singular forms “a” and “an” are intended to include the plural forms as well, unless the context clearly indicates otherwise. It will be further understood that the terms “comprises,” “comprising,” “have,” “having,” “includes,” and “including,” when used in this specification, specify the presence of the stated features, integers, steps, operations, elements, and/or components, but do not preclude the presence or addition of one or more other features, integers, steps, operations, elements, components, and/or groups thereof.

As used herein, the term “substantially,” “about,” “approximately,” and similar terms are used as terms of approximation and not as terms of degree, and are intended to account for the inherent deviations in measured or calculated values that would be recognized by those of ordinary skill in the art. “About” or “approximately,” as used herein, is inclusive of the stated value and refers to being within an acceptable range of deviation for the particular value as determined by one of ordinary skill in the art, considering the measurement in question and the error associated with measurement of the particular quantity (i.e., the limitations of the measurement system). For example, “about” may refer to being within one or more standard deviations, or within ± 30%, 20%, 10%, and/or 5% of the stated value.

When one or more embodiments may be implemented differently, a specific process order may be performed differently from the described order. For example, two consecutively described processes may be performed substantially at the same time or performed in an order opposite or different to the described order.

Also, any numerical range disclosed and/or recited herein is intended to include all sub-ranges of the same numerical precision subsumed within the recited range. For example, a range of “1.0 to 10.0” is intended to include all subranges between (and including) the recited minimum value of 1.0 and the recited maximum value of 10.0, for example, having a minimum value equal to or greater than 1.0 and a maximum value equal to or less than 10.0, such as, for example, 2.4 to 7.6. Any maximum numerical limitation recited herein is intended to include all lower numerical limitations subsumed therein, and any minimum numerical limitation recited in this specification is intended to include all higher numerical limitations subsumed therein. Accordingly, Applicant reserves the right to amend this specification, including the claims, to expressly recite any sub-range subsumed within the ranges expressly recited herein. All such ranges are intended to be inherently described in this specification such that amending to expressly recite any such subranges would comply with the requirements of 35 U.S.C. § 112(a) and 35 U.S.C. § 132(a).

The electronic or electric devices and/or any other relevant devices or components according to one or more embodiments of the disclosure described herein may be implemented utilizing any suitable hardware, firmware (e.g., an application-specific integrated circuit), software, or a combination of software, firmware, and hardware. For example, the various components of these devices may be formed on one integrated circuit (IC) chip or on separate IC chips. Further, the various components of these devices may be implemented on a flexible printed circuit film, a tape carrier package (TCP), a printed circuit board (PCB), and/or formed on one substrate.

Further, the various components of these devices may be a process and/or thread, running on one or more processors, in one or more computing devices, executing computer program instructions and interacting with other system components for performing the various functionalities described herein. The computer program instructions are stored in a memory which may be implemented in a computing device using a standard memory device, such as, for example, a random access memory (RAM). The computer program instructions may also be stored in other non-transitory computer readable media such as, for example, a CD-ROM, flash drive, and/or the like. Also, a person of skill in the art should recognize that the functionality of one or more suitable computing devices may be combined or integrated into a single computing device, or the functionality of a particular computing device may be distributed across one or more other computing devices without departing from the spirit and scope of the disclosure.

Unless otherwise defined, all terms (including technical and scientific terms) used herein have the same meaning as commonly understood by one of ordinary skill in the art to which the disclosure belongs. It will be further understood that terms, such as those defined in commonly used dictionaries, should be interpreted as having a meaning for example consistent with their meaning in the context of the relevant art and/or the present specification, and should not be interpreted in an idealized or overly formal sense, unless expressly so defined herein.

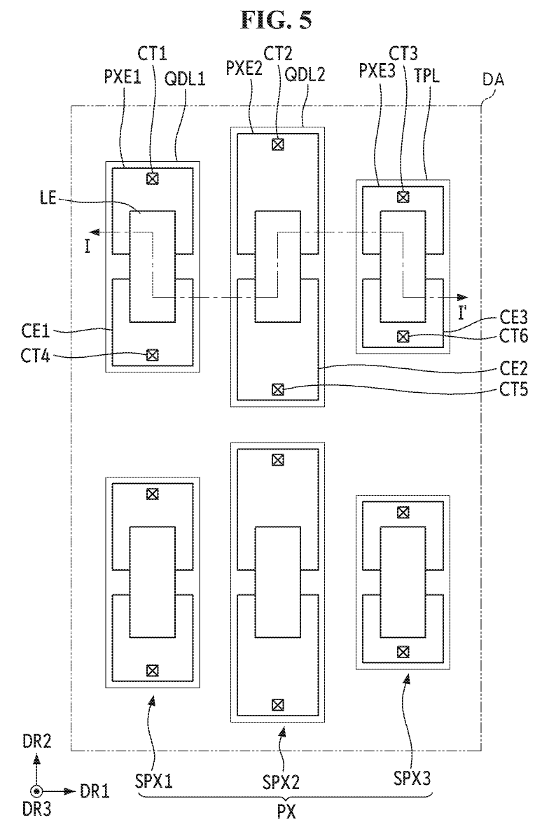

FIG. 5 is a layout diagram illustrating pixels of a display area according to one or more embodiments.

Referring to FIG. 5, each of the plurality of pixels PX of the display area DA may include three sub-pixels SPX1, SPX2, and SPX3, but the embodiments of the present disclosure are not limited thereto and may include, for example, a display area DA with four sub-pixels. When each of the plurality of pixels PX includes three sub-pixels SPX1, SPX2, and SPX3, a first sub-pixel SPX1, a second sub-pixel SPX2, and a third sub-pixel SPX3 may be included.

The plurality of pixels PX may be arranged in a matrix form. In each of the plurality of pixels PX, the first sub-pixel SPX1, the second sub-pixel SPX2, and the third sub-pixel SPX3 may be arranged in a first direction DR1.

When each of the plurality of pixels PX includes three sub-pixels SPX1, SPX2, and SPX3, the first sub-pixel SPX1 may be to emit light of a first color, the second sub-pixel SPX2 may be to emit light of a second color, and the third sub-pixel SPX3 may be to emit light of a third color. Here, the light of the first color may be light in a blue wavelength band, the light of the second color may be light in a green wavelength band, and the light of the third color may be light in a red wavelength band. For example, the blue wavelength band may refer to light having a main peak wavelength in the wavelength band from approximately 370nm to 460nm, the green wavelength band may refer to light having a main peak wavelength in the wavelength band from approximately 480nm to 560nm, and the red wavelength band may refer to light having a main peak wavelength in the wavelength band from approximately 600nm to 750nm.

In one or more embodiments, when each of the plurality of pixels PX includes four sub-pixels, the first sub-pixel may be to emit light of a first color, the second and fourth sub-pixels may be to emit light of a second color, and the third sub-pixel may be to emit light of a third color. In some embodiments, the first sub-pixel may be to emit light of a first color, the second sub-pixel may be to emit light of a second color, the third sub-pixel may be to emit light of a third color, and the fourth sub-pixel may be to emit light of a fourth color. In this case, the fourth color light may be white light.

The first sub-pixel SPX1 may include a first pixel electrode PXE1, a plurality of light emitting elements LE, and a first light conversion layer QDL1. The second sub-pixel SPX2 may include a second pixel electrode PXE2, a plurality of light emitting elements LE, and a second light conversion layer QDL2. The third sub-pixel SPX3 may include a third pixel electrode PXE3, a plurality of light emitting elements LE, and a third light conversion layer QDL3.

In each of the first sub-pixel SPX1, the second sub-pixel SPX2, and the third sub-pixel SPX3, the pixel electrodes PXE1, PXE2, and PXE3 may be arranged with each other in the second direction DR2, and the common electrodes CE1, CE2, and CE3 may be arranged with each other in the second direction DR2. Each of the pixel electrodes PXE1, PXE2, and PXE3 and the common electrodes CE1, CE2, and CE3 may have a rectangular plane shape (e.g., in a plan view), but the embodiments of the present disclosure are not limited thereto. The area of the first pixel electrode PXE1 may be the same (or substantially the same) as the area of the first common electrode CE1, the area of the second pixel electrode PXE2 may be the same (or substantially the same) as the area of the second common electrode CE2, and the area of the third pixel electrode PXE3 may be the same (or substantially the same) as the area of the third common electrode CE3, but the embodiment of the present disclosure is not limited thereto.

For example, as shown in FIG. 5, when the light conversion efficiency of the second light conversion layer QDL2 is lower than the light conversion efficiency of the first light conversion layer QDL1, the area of the second pixel electrode PXE2 may be larger than the area of the first pixel electrode PXE1. Furthermore, while the light transmission layer TPL may directly transmit the light of the light emitting element LE, the first light conversion layer QDL1 need to convert the light, and therefore the area of the first pixel electrode PXE1 may be larger than the area of the third pixel electrode PXE3, and the area of the first common electrode CE1 may be larger than the area of the third common electrode CE3.

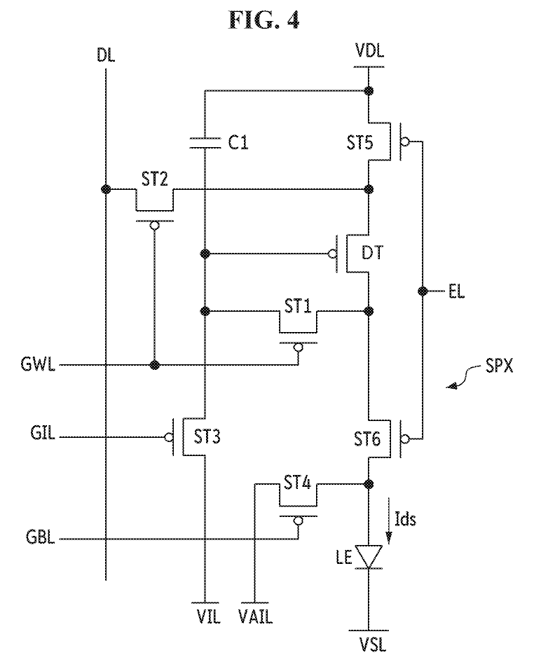

Each of the pixel electrodes PXE1, PXE2, and PXE3 may be electrically connected to at least one transistor through the pixel connection hole CT1, CT2, and CT3, respectively. For example, each of the pixel electrodes PXE1, PXE2, and PXE3 may be electrically connected to the second electrode of the fourth transistor (ST4 in FIG. 4) and the second electrode of the sixth transistor (ST6 in FIG. 4) of the corresponding sub-pixel.

The first common electrode CE1 may be connected to a second power supply line VSL to which a second driving voltage VSS is applied through a first common connection hole CT4. The second common electrode CE2 may be connected to a second power supply line VSL through a second common connection hole CT5. The third common electrode CE3 may be connected to the second power supply line VSL through a third common connection hole CT6. Therefore, the second driving voltage VSS may be applied to each of the common electrodes CE1, CE2, and CE3. The pixel electrodes PXE1, PXE2, and PXE3 may each independently be referred to as an anode electrode or a first electrode, and the common electrodes CE1, CE2, and CE3 may each independently be referred to as a cathode electrode or a second electrode.

A plurality of light emitting elements LE may be arranged on the pixel electrodes PXE1, PXE2, and PXE3 and the common electrode CE1, CE2, and CE3. Each of the plurality of light emitting elements LE may have a rectangular planar shape, but the embodiment of the present disclosure is not limited thereto. For example, each of the plurality of light emitting elements LE may have a circular planar shape.

The first light conversion layer QDL1 may completely overlap with the plurality of light emitting elements LE of the first sub-pixel SPX1. The first light conversion layer QDL1 may convert (e.g., shift) the peak wavelength of incident light into light of another set or specific peak wavelength and emit the converted light. For example, the first light conversion layer QDL1 may convert and/or shift third light emitted from the plurality of light emitting elements LE of the first sub-pixel SPX1 into first light.

The second light conversion layer QDL2 may completely overlap with the plurality of light emitting elements LE of the second sub-pixel SPX2. The area of the second light conversion layer QDL2 may be larger than the area of the second pixel electrode PXE2. The second light conversion layer QDL2 may convert and/or shift the peak wavelength of incident light into light of another set or specific peak wavelength and emit the converted light. For example, the second light conversion layer QDL2 may convert and/or shift the third light emitted from the plurality of light emitting elements LE of the second sub-pixel SPX2 into the second light.

The light transmission layer TPL may completely overlap the plurality of light emitting elements LE of the third sub-pixel SPX3. The light transmission layer TPL may directly transmit the incident light. For example, the light transmission layer TPL may directly transmit the third light emitted from the plurality of light emitting elements LE of the third sub-pixel SPX3.

When the light emitting element LE of the first sub-pixel SPX1 can emit light of a first color, the light emitting element LE of the second sub-pixel SPX2 can emit light of a second color, and the light emitting element LE of the third sub-pixel SPX3 can emit light of a third color, the light conversion layers QDL1 and QDL2 and the light transmission layer TPL may not be provided.

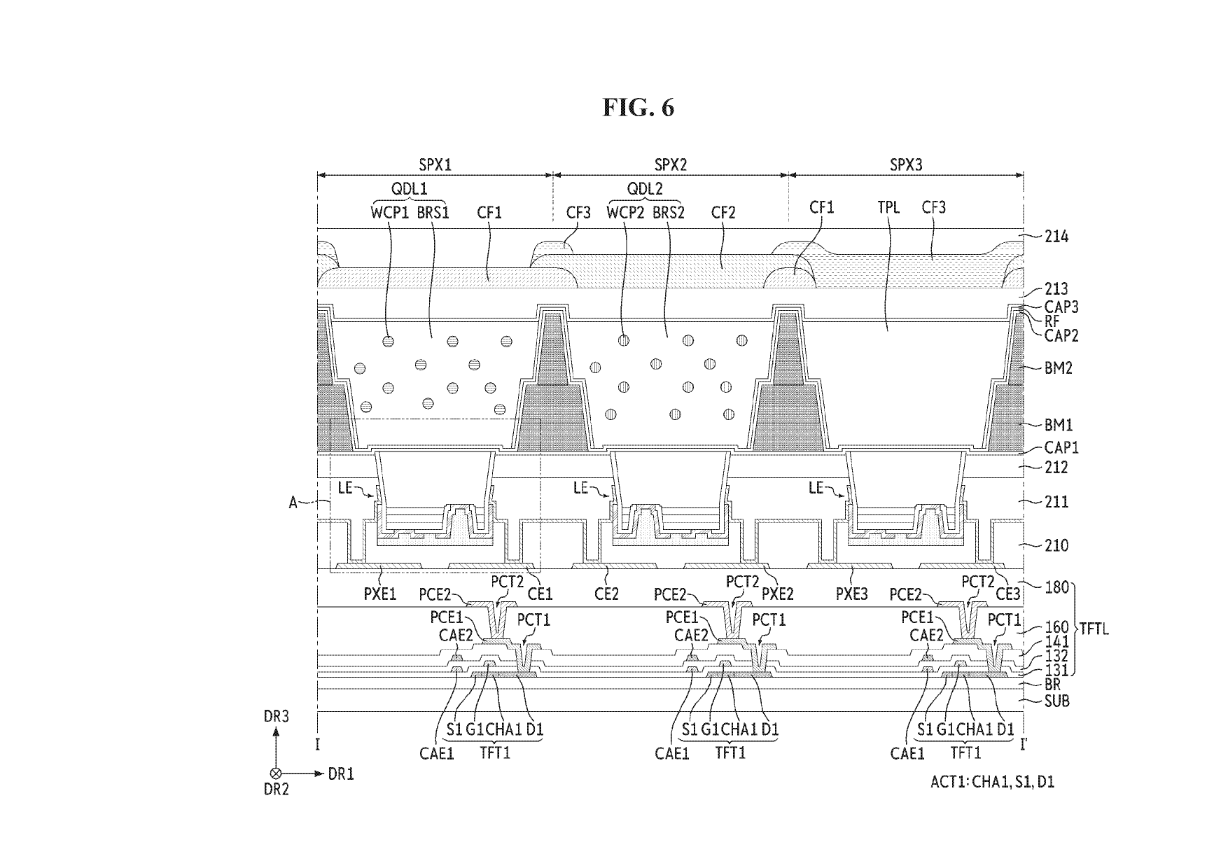

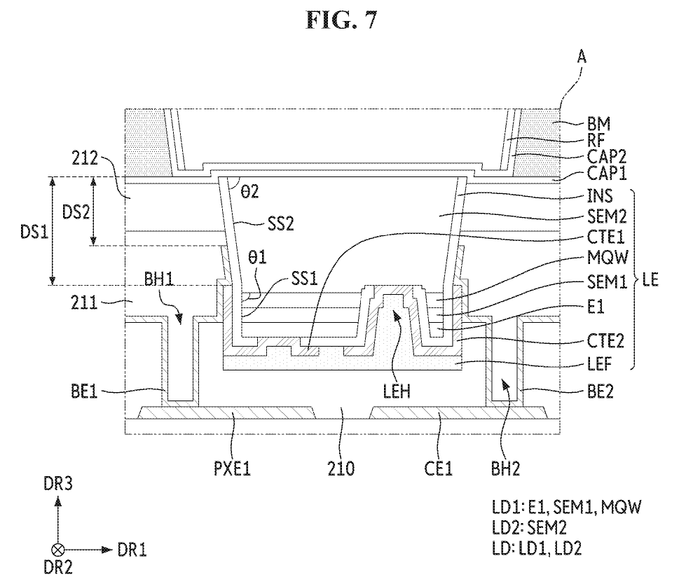

FIG. 6 is a cross-sectional view illustrating an example cross-section of a display panel corresponding to lines I-I’ in FIG. 5. FIG. 7 is a cross-sectional view illustrating an example of area A in FIG. 6 in more detail.

Referring to FIGS. 6 and 7, a substrate SUB may be made of an insulating material such as glass, polymer resin, and/or the like. If the substrate SUB is made of polymer resin, it may be a flexible substrate that may be stretched. The polymer resin may be acrylic resin, epoxy resin, phenolic resin, polyamide resin, polyimide resin, and/or the like.

A barrier film BR may be arranged on the substrate SUB. The barrier film BR is a film that protects the thin film transistors TFT1 of the thin film transistor layer TFTL from moisture penetrating through the substrate SUB which is vulnerable to moisture permeation. The barrier film BR may be formed of a plurality of inorganic films that are alternately stacked.

A thin film transistor TFT1 may be arranged on the barrier film BR. The thin film transistor TFT1 may be either the fourth transistor ST4 or the sixth transistor ST6 shown in FIG. 4. The thin film transistor TFT1 may include a first active layer ACT1 and a first gate electrode G1.

The first active layer ACT1 of the thin film transistor TFT1 may be arranged on the barrier film BR. The first active layer ACT1 of the thin film transistor TFT1 may include polycrystalline silicon, monocrystalline silicon, low-temperature polycrystalline silicon, and/or amorphous silicon. In one or more embodiments, the first active layer ACT1 of the thin film transistor TFT1 may include an oxide semiconductor including IGZO (indium (In), gallium (Ga), zinc (Zn), and oxygen (O)), IGZTO (indium (In), gallium (Ga), zinc (Zn), tin (Sn), and oxygen (O)), and/or IGTO (indium (In), gallium (Ga), tin (Sn), and oxygen (O)).

The first active layer ACT1 may include a first channel area CHA1, a first source area S1, and a first drain area D1. The first channel area CHA1 may be an area overlapping the first gate electrode G1 in the third direction DR3, which is the thickness direction of the substrate SUB. The first source area S1 may be arranged on one side of the first channel area CHA1, and the first drain area D1 may be arranged on the other side of the first channel area CHA1. The first source area S1 and the first drain area D1 may be areas that do not overlap with the first gate electrode G1 in the third direction DR3. The first source area S1 and the first drain area D1 may be conductive areas in which semiconductor materials are doped with ions.

A first gate may include a first gate insulating film 131 that may be arranged on the first channel area CHA1, the first source area S1, and the first drain area D1 of the thin film transistor TFT1.

A first gate metal layer may be arranged on the first gate insulating film 131. The first gate metal layer may include a first gate electrode G1 of a thin film transistor TFT1 and a first capacitor electrode CAE1. The first gate electrode G1 may overlap the first active layer ACT1 in the third direction DR3. Although the first gate electrode G1 and the first capacitor electrode CAE1 are illustrated as being arranged apart from each other in FIG. 6, the first gate electrode G1 and the first capacitor electrode CAE1 may be connected to each other.

A second gate insulating film 132 may be arranged on the first gate electrode G1 of the thin film transistor TFT1 and the first capacitor electrode CAE1.

A second gate metal layer may be arranged on the second gate insulating film 132. The second gate metal layer may include a second capacitor electrode CAE2. The second capacitor electrode CAE2 may overlap the first capacitor electrode CAE1 of the thin film transistor TFT1 in the third direction DR3. Because the second gate insulating film 132 has a set or predetermined dielectric constant, the capacitor (C1 in FIG. 4) may be formed by the first capacitor electrode CAE1, the second capacitor electrode CAE2, and the second gate insulating film 132 arranged between them.

A first interlayer insulating film 141 may be arranged on the second capacitor electrode CAE2.

A first data metal layer may be arranged on the first interlayer insulating film 141. The first data metal layer may include a first source connection electrode PCE1. The first source connection electrode PCE1 may be connected to the first drain area D1 of the first active layer ACT1 through a first source contact hole PCT1 penetrating the first gate insulating film 131, the second gate insulating film 132, and the first interlayer insulating film 141.

A first planarization organic film 160 may be arranged on the first source connection electrode PCE1 to planarize or reduce a step caused by the thin film transistor TFT1.

A second data metal layer may be arranged on the first planarization organic film 160. The second data metal layer may include a second source connection electrode PCE2. The second source connection electrode PCE2 may be connected to the first source connection electrode PCE1 through a second pixel contact hole (PCT2) penetrating the first planarization organic film 160.

A second planarization organic film 180 may be arranged on the second source connection electrode PCE2.

The barrier film BR, the first gate insulating film 131, the second gate insulating film 132, the third gate insulating film 133, and the first interlayer insulating film 141 may be formed of an inorganic film (e.g., an inorganic material), such as silicon nitride (SiNₓ, e.g., Si₃N₄), silicon oxide nitride (SiON, e.g., Si₂N₂O), silicon oxide (SiOₓ, e.g., SiO₂), titanium oxide (TiOₓ, e.g., TiO₂), and/or aluminum oxide (AlOₓ, e.g., Al₂O₃).

The first gate metal layer, the second gate metal layer, the first data metal layer, and the second data metal layer may be formed as a single layer or multiple layers of any one selected from among molybdenum (Mo), aluminum (Al), chromium (Cr), gold (Au), titanium (Ti), nickel (Ni), neodymium (Nd), and copper (Cu), or an alloy thereof.

The first planarization organic film 160 and the second planarization organic film 180 may be formed of an organic film (e.g., an organic material) such as an acrylic resin, an epoxy resin, a phenolic resin, a polyamide resin, a polyimide resin, and/or the like.

A light emitting element layer may be arranged on the second planarization organic film 180. The light emitting element layer may include pixel electrodes PXE1, PXE2, PXE3, light emitting elements LE, a common electrode CE, and a first organic layer 210.

A pixel electrode layer including pixel electrodes PXE1, PXE2, and PXE3 and common electrodes CE1, CE2, and CE3 may be arranged on a second planarization organic film 180.

Each of the first pixel electrode PXE1, the second pixel electrode PXE2, and the third pixel electrode PXE3 may be connected to a second source connection electrode PCE2 through a connection hole (CT1/CT2/CT3 in FIG. 5) penetrating the second planarization organic film 180. Each of the pixel electrodes PXE1, PXE2, and PXE3 may be connected to a first source area S1 or a first drain area D1 of a thin film transistor TFT1 through the first source connection electrode PCE1 and the second source connection electrode PCE2. Therefore, a voltage controlled or selected by the thin film transistor TFT1 may be applied to each of the pixel electrodes PXE1, PXE2, and PXE3.

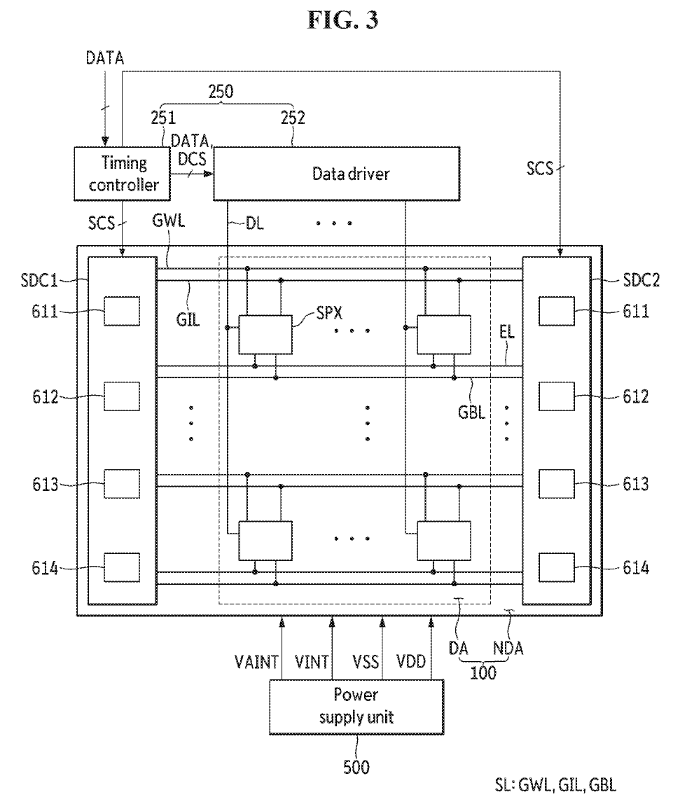

The common electrodes CE1, CE2, and CE3 may be connected to a second power supply line (VSL in FIG. 4) to which a second driving voltage (VSS in FIG. 3) is applied through a common connection hole (CT4/CT5/CT6 in FIG. 5). The second common electrode CE2 may be connected to the second power supply line VSL through the second common connection hole CT5. The third common electrode CE3 may be connected to the second power supply line VSL through the third common connection hole CT6. Therefore, the second driving voltage VSS may be applied to each of the common electrodes CE1, CE2, and CE3.

The pixel electrode layer may be formed as a single layer or multiple layers of any one selected from among molybdenum (Mo), aluminum (Al), chromium (Cr), gold (Au), titanium (Ti), nickel (Ni), neodymium (Nd), and copper (Cu), or alloys thereof. For example, the pixel electrode layer may be made of copper (Cu) having suitably low surface resistance to lower the resistance of each of the pixel electrodes PXE1, PXE2, and PXE3.

A first organic layer 210 may be arranged on each of the pixel electrode layers. For example, the first organic layer 210 may cover at least a portion of the pixel electrodes PXE1, PXE2, and PXE3 and at least a portion of the common electrodes CE1, CE2, and CE3.

The first organic layer 210 serves to temporarily fix (e.g., affix) and/or adhere an upper member (e.g., a light emitting element LE). For example, the first organic layer 210 may be a film for temporarily adhering an upper member (e.g., a light emitting element LE) on each of the pixel electrodes PXE1, PXE2, and PXE3 and the common electrodes CE1, CE2, and CE3. To facilitate adhesion, the thickness of the first organic layer 210 may be greater than the thickness of each of the pixel electrodes PXE1, PXE2, and PXE3 and the common electrodes CE1, CE2, and CE3, and may be greater than the thickness of the contact electrode CTE. The thickness of the first organic layer 210 may be about 2 μm but the present disclosure is not limited thereto.

The first organic layer 210 may be a photosensitive organic film such as a photoresist. In one or more embodiments, the first organic layer 210 may be formed of an acrylic resin, an epoxy resin, a phenolic resin, a polyamide resin, a polyimide resin, and/or the like.

A plurality of light emitting elements LE may be arranged on the first organic layer 210. In FIGS. 6 and 7, the light emitting elements LE are illustrated as flip-type or kind micro LED. A flip-type or kind micro LED refers to an LED that has contact electrodes CTE1 and CTE2 formed on one side (e.g., the bottom side) of the light emitting element LE.

The light emitting element LE may have one or more suitable shapes, such as a rod, wire, tube, and/or the like, a polygonal column shape such as a cube, a rectangular parallelepiped, a hexagonal column, and/or the like, and/or a shape that extends in one direction but has a partially sloped outer surface.

Each of the plurality of light emitting elements LE may be formed from an inorganic material such as gallium nitride (GaN).

Each of the plurality of light emitting elements LE may be formed by growing on a semiconductor substrate such as a silicon substrate and/or a sapphire substrate. The plurality of light emitting elements LE may be transferred onto the pixel electrode layer of the display panel 100 directly from the semiconductor substrate or through a relay substrate. In one or more embodiments, a plurality of light emitting elements LE may be transferred onto the pixel electrode layer of the display panel 100 by an electrostatic method using an electrostatic head and/or a stamp method using an elastic polymer material such as Polydimethylsiloane (PDMS) and/or silicone as a transfer substrate.

Each of the plurality of light emitting elements LE may include a conductive layer E1, a first semiconductor layer SEM1, an active layer MQW, a second semiconductor layer SEM2, a protective film INS, a first contact electrode CTE1, a second contact electrode CTE2, and an element planarization layer LEF.

The conductive layer E1 may be arranged on the bottom surface of the first semiconductor layer SEM1. In FIG. 7, the conductive layer E1 is illustrated as covering the entire bottom surface of the first semiconductor layer SEM1, but the embodiment of the present disclosure is not limited thereto. In some embodiments, the conductive layer E1 may be arranged on a portion of the bottom surface of the first semiconductor layer SEM1. The conductive layer E1 may include one selected from among molybdenum (Mo), aluminum (Al), chromium (Cr), gold (Au), titanium (Ti), nickel (Ni), neodymium (Nd), and copper (Cu).

The first semiconductor layer SEM1 may be arranged on the conductive layer E1. The first semiconductor layer SEM1 may be formed of a semiconductor material layer doped with a first conductive dopant, such as magnesium (Mg), zinc (Zn), calcium (Ca), strontium (Sr), barium (Ba), and/or the like, for example, gallium nitride (GaN).

The active layer MQW may be arranged on the first semiconductor layer SEM1. The active layer MQW may be to emit light by combining electron-hole pairs according to an electrical signal applied through the first semiconductor layer SEM1 and the second semiconductor layer SEM2.

The active layer MQW may include a material having a single or multi-quantum well structure. When the active layer MQW includes a material having a multi-quantum well structure, it may have a structure in which a plurality of well layers and barrier layers are alternately stacked. In some embodiments, the well layer may be formed of indium gallium nitride (InGaN), and the barrier layer may be formed of gallium nitride (GaN) and/or aluminum gallium nitride (AlGaN), but embodiments of the present disclosure are not limited thereto.

In one or more embodiments, the active layer MQW may have a structure in which semiconductor materials having a suitably high band gap energy and semiconductor materials having a suitably low band gap energy are alternately stacked with each other, may include other suitable Group three to five semiconductor materials according to the wavelength range of emitted light.

In one or more embodiments, when the active layer MQW includes InGaN, the color of the emitted light may vary depending on the content (e.g., amount) of indium (In). For example, as the content (e.g., amount) of indium (In) increases, the wavelength band of light emitted by the active layer may shift to the red wavelength band, and as the content (e.g., amount) of indium (In) decreases, the wavelength band of light emitted by the active layer may shift to the blue wavelength band. For example, the content (e.g., amount) of indium (In) in the active layer MQW of the light emitting element LE that emits the third light (light in the blue wavelength band) may be approximately 10 wt% to 20 wt%.

The second semiconductor layer SEM2 may be arranged on the first semiconductor layer SEM1. The second semiconductor layer SEM2 may be a semiconductor material layer doped with a second conductive dopant such as silicon (Si), germanium (Ge), tin (Sn), and/or the like, for example, gallium nitride (GaN).

An electron blocking layer may be arranged between the first semiconductor layer SEM1 and the active layer MQW. The electron blocking layer may be a layer to suppress, prevent, or reduce too many electrons from flowing into the active layer MQW. For example, the electron blocking layer may be aluminum gallium nitride (AlGaN) and/or p-type or kind aluminum gallium nitride (AlGaN) doped with p-type or kind magnesium (Mg). The electronic blocking layer may not be provided.

A superlattice layer may be arranged between the active layer MQW and the second semiconductor layer SEM2. The superlattice layer may be a layer for relieving stress between the second semiconductor layer SEM2 and the active layer MQW. For example, the superlattice layer may be aluminum gallium nitride (AlGaN) and/or p-type or kind aluminum gallium nitride (AlGaN) doped with p-type or kind magnesium (Mg). In some embodiments, the superlattice layer may not be provided.

The first semiconductor layer SEM1, the active layer MQW, and the second semiconductor layer SEM2 of the light emitting element LE may be referred to as element rod LD.

The element rod LD may include a first element rod LD1 and a second element rod LD2 that are distinguished by a change in the inclination angle of the side surface.

The first element rod LD1 may include a first sidewall SS1 having a first inclination angle θ1. The first inclination angle θ1 of the first sidewall SS1 may be formed to be about 90 degrees as shown in FIG. 7 but the present disclosure is not limited thereto. For example, the first inclination angle θ1 may be 70 degrees or more and less than 90 degrees. The first inclination angle θ1 is an angle between an extension of a contact surface of the first element rod LD1 and the second element rod LD2 and the first sidewall SS1 of the first element rod LD1.

The first element rod LD1 may include a conductive layer E1, a first semiconductor layer SEM1, and an active layer MQW. The first element rod LD1 may have a height in the range of 0.3 μm to 0.5 μm but the present disclosure is not limited thereto.

The second element rod LD2 is arranged on the first element rod LD1.

The second element rod LD2 may include a second sidewall SS2 having a second inclination angle θ2. The second inclination angle θ2 of the second sidewall SS2 may be 60 degrees or more and 80 degrees or less. Further, the second inclination angle θ2 may be smaller than the first inclination angle θ1. Therefore, the second sidewall SS2 may be formed with a regular taper.

The second inclination angle θ2 includes an angle between the top surface of the second semiconductor layer SEM2 and the second sidewall SS2 of the second element rod LD2.

The side surfaces of the first element rod LD1 and the second element rod LD2 may not be aligned with each other and may have a step but the present disclosure is not limited thereto. The side surfaces of the first element rod LD1 and the second element rod LD2 may not be aligned with each other and may have a step but the present disclosure is not limited thereto.

The second element rod LD2 may include the second semiconductor layer SEM2.

The protective film INS may be a film for protecting the bottom surface and the side surface of the light emitting element LE. The protective film INS may be arranged on the bottom surface and the side surface of the conductive layer E1 and the side surface of the semiconductor layers SEM1, MQW, and SEM2. For example, the protective film INS may be arranged on the bottom surface and side surface of the conductive layer E1, the side surface of the first semiconductor layer SEM1, the side surface of the active layer MQW, and the side surface of the second semiconductor layer SEM2.

The protective film INS may be formed of an inorganic film, such as silicon nitride (SiNₓ, e.g., Si₃N₄), silicon oxide nitride (SiON, e.g., Si₂N₂O), silicon oxide (SiOₓ, e.g., SiO₂), titanium oxide (TiOₓ, e.g., TiO₂), and/or aluminum oxide (AlOₓ, e.g., Al₂O₃). The protective film INS may be arranged from one end to the other end of the side surface of the light emitting element LE but may be arranged to be spaced apart from one end due to a process error.

A hole LEH may be formed to penetrate the conductive layer E1, the first semiconductor layer SEM1, and the active layer MQW of the light emitting element LE to expose the second semiconductor layer SEM2. The hole LEH may have a rectangular planar shape, but the embodiments of the present disclosure are not limited thereto. For example, the hole LEH may have a polygonal planar shape such as a circle, oval, or square.

In one or more embodiments, the protective film INS may be arranged on the sidewall of the conductive layer E1 exposed in the hole LEH, the sidewall of the first semiconductor layer SEM1, and the sidewall of the active layer MQW. The protective film INS may not cover the second semiconductor layer SEM2 in the hole LEH. Therefore, the second semiconductor layer SEM2 exposed by the hole LEH may be exposed without being covered by the protective film INS.

The first contact electrode CTE1 may be arranged on at least one side surface and a bottom surface of the first element rod LD1. The first contact electrode CTE1 may be arranged on a bottom surface of the conductive layer E1 that is exposed and not covered by the protective film INS and may extend to a side surface of the first element rod LD1. The first contact electrode CTE1 may be electrically connected to the conductive layer E1.

The second contact electrode CTE2 may be arranged on at least one side surface and a bottom surface of the first element rod LD1. In this case, the first contact electrode CTE1 may be arranged on a first side surface of the first element rod LD1 and a first side surface of the conductive layer E1, and the second contact electrode CTE2 may be arranged on the second side surface of the first element rod LD1 and the second side surface of the conductive layer E1.

The second contact electrode CTE2 may be arranged on the protective film INS arranged in the hole LEH and the second semiconductor layer SEM2 exposed without being covered by the protective film INS in the hole LEH. Thus, the second contact electrode CTE2 may be electrically connected to the second semiconductor layer SEM2 in the hole LEH.

The first contact electrode CTE1 and the second contact electrode CTE2 may be arranged on at least a portion of a side surface of the first element rod LD1. The side surface of the second element rod LD2 may be exposed without being covered by the first contact electrode CTE1 and the second contact electrode CTE2.

The first contact electrode CTE1 and the second contact electrode CTE2 may include one selected from among molybdenum (Mo), aluminum (Al), chromium (Cr), gold (Au), titanium (Ti), nickel (Ni), neodymium (Nd), and copper (Cu). For example, the first contact electrode CTE1 and the second contact electrode CT may be formed as a two-layer structure of chromium (Cr) and gold (Au), a three-layer structure of titanium (Ti), aluminum (Al), and titanium (Ti), or a three-layer structure of indium tin oxide (ITO), silver (Ag), and indium tin oxide (ITO) to increase reflectivity.

Each of first contact electrode CTE1 and the second contact electrode CTE2 may be arranged on three sides of the first element rod LD1. For example, when the first element rod LD1 includes the first to fourth sides, the first contact electrode CTE1 may be arranged on the first side, the second side, and the third side, and the second contact electrode CTE2 may be arranged on the second side, the third side, and the fourth side.

An element planarization layer LEF may be arranged on one surface of a first element rod LD1 on which contact electrodes CTE1 and CTE2 are arranged.

The element planarization layer LEF may flatten or reduce a difference in surface height formed by the first contact electrode CTE1, the second contact electrode CTE2, and the hole LEH. For example, the element planarization layer LEF fills an opening defined by a protective film INS of the first element rod LD1 and a step (e.g., height difference) formed by the hole LEH to flatten (e.g., substantially flatten or substantially planarize) one surface of the first element rod LD1. The element planarization layer LEF has a flat or substantially flat surface. The element planarization layer LEF may be filled in the hole LEH.

The side surfaces of the element planarization layer LEF and the contact electrodes CTE1 and CTE2 may be aligned to coincide with each other but are not limited thereto.

The element planarization layer LEF may be arranged between the contact electrodes CTE1 and CTE2 and the first organic layer 210. The element planarization layer LEF may be at least partially buried in the first organic layer 210. One side and a side surface of the element planarization layer LEF may be in direct contact with the first organic layer 210.

The element planarization layer LEF may be formed of an insulating organic material such as an acrylic resin, an epoxy resin, a phenolic resin, a polyamide resin, a polyimide resin, and/or the like, but the present disclosure is not limited thereto.

The distance between the element planarization layer LEF and the first contact electrode CTE1 and the distance between the element planarization layer LEF and the second contact electrode CTE2 may be substantially the same.

The connection electrodes BE1 and BE2 may electrically connect the light emitting element LE and the pixel electrode layer.

In one or more embodiments, the first connection electrode BE1 connects the first contact electrode CTE1 of the light emitting element LE and the pixel electrode PXE1, PXE2, and PXE3.

The first connection electrode BE1 may be arranged on the first contact electrode CTE1 arranged on the side of the first element rod LD1. The first connection electrode BE1 may be connected to the pixel electrode PXE1, PXE2, and PXE3 exposed through the first connection hole BH1 penetrating the first organic layer 210. In some embodiments, the first connection electrode BEb extends along the top surface of the first organic layer 210 and one surface of the first contact electrode CTE1.

The second connection electrode BE2 may be arranged on the second contact electrode CTE2 arranged on the side of the first element rod LD1. The second connection electrode BE2 may be connected to the common electrode CE1, CE2, and CE3 exposed through the second connection hole BH2 penetrating the first organic layer 210. Furthermore, the second connection electrode BE2 extends along the top surface of the first organic layer 210 and one surface of the second contact electrode CTE2. For example, the connection electrodes BE1 and BE2 may be arranged to cover the entirety of the protective film INS that is exposed and not covered by the contact electrodes CTE1 and CTE2.

In the third direction DR3, a distance DS2 between the first connection electrode BE1 and the second connection electrode BE2 and the top surface of the light emitting element LE may be smaller than a distance DS1 between the first contact electrode CTE1 and the second contact electrode CTE2 and the top surface of the light emitting element LE, but the embodiment of the present disclosure is not limited thereto. For example, in the third direction DR3, the distance DS2 between the first connection electrode BE1 and the second connection electrode BE2 and the top surface of the light emitting element LE may be substantially the same as the distance DS1 between the first contact electrode CTE1 and the second contact electrode CTE2 and the top surface of the light emitting element LE.

A second organic layer 211 may be arranged to cover a portion of the side surfaces of the plurality of light emitting elements LE. Further, the second organic layer 211 may be arranged to cover the connection electrodes BE1 and BE2.

The third organic layer 212 may be arranged on the second organic layer 211. The third organic layer 212 may be arranged to cover another portion of the side surfaces of each of the plurality of light emitting elements LE. The third organic layer 212 may be arranged on the protective film INS and the connection electrodes BE1 and BE2 that are not covered by the second organic layer 211 as shown in FIG. 7, but the embodiment of the present disclosure is not limited thereto. In one or more embodiments, the entire connection electrodes BE1 and BE2 may be covered by the second organic layer b. The upper surfaces of each of the plurality of light emitting elements LE may be exposed without being covered by the third organic layer 212.

The second organic layer 211 and the third organic layer 212 are layers for flattening or reducing the steps (e.g., height differences) caused by the plurality of light emitting elements LE. If the height of the second organic layer 211 is arranged to cover most of the side surfaces of each of the plurality of light emitting elements LE, the third organic layer 212 may not be provided.

The second organic layer 211 and the third organic layer 212 may be formed of an organic film such as an acrylic resin, an epoxy resin, a phenolic resin, a polyamide resin, a polyimide resin, and/or the like.

The first capping layer CAP1 may be arranged on the third organic layer 212 and the light emitting element LE.

A light blocking layer BM, a first light conversion layer QDL1, a second light conversion layer QDL2, and a light transmission layer TPL may be arranged on the first capping layer CAP1. The first light conversion layer QDL1, the second light conversion layer QDL2, and the light transmission layer TPL may be formed by the partition of the light blocking layer BM. Thus, the first light conversion layer QDL1 may be arranged on the first capping layer CAP1 in the first sub-pixel SPX1, the second light conversion layer QDL2 may be arranged on the first capping layer CAP1 in the second sub-pixel SPX2, and the light transmission layer TPL may be arranged on the first capping layer CAP1 in the third sub-pixel SPX3. The light blocking layer BM may not overlap the plurality of light emitting elements LE in the third direction DR3.

The first light conversion layer QDL1 may convert a portion of the third light (light in the blue wavelength band) incident from the light emitting element LE into first light (light in the red wavelength band). The first light conversion layer QDL1 may include a first base resin BRS1 and a first wavelength conversion particle WCP1. The first base resin BRS1 may include a light-transmitting organic material. The first wavelength conversion particle WCP1 may convert a portion of the third light (light in the blue wavelength band) incident from the light emitting element LE into first light (light in the red wavelength band).

The second light conversion layer QDL2 may convert a portion of the third light (light in the blue wavelength band) incident from the light emitting element LE into second light (light in the green wavelength band). The second light conversion layer QDL2 may include a second base resin BRS2 and a second wavelength conversion particle WCP2. The second base resin BRS2 may include a light-transmitting organic material. The second wavelength conversion particle WCP2 may convert a portion of the third light (light in the blue wavelength band) incident from the light emitting element LE into second light (light in the green wavelength band).

The light transmission layer TPL may include a light-transmitting organic material.

For example, the first base resin BRS1, the second base resin BRS2, and the light transmission layer TPL may each independently include an epoxy-based resin, an acrylic-based resin, a cado-based resin, and/or an imide-based resin. The first and second wavelength conversion particles WCP1 and WCP2 may be quantum dots (QD), quantum rods, fluorescent materials, and/or phosphorescent materials.

The light blocking layer BM may include a first light blocking layer BM1 and a second light blocking layer BM2 that are sequentially laminated. A length of the first light blocking layer BM1 in the first direction DR1 and/or a length of the first light blocking layer BM1 in the second direction DR2 may be wider than a length of the second light blocking layer BM2 in the first direction DR1 and/or a length of the second light blocking layer BM2 in the second direction DR2, respectively. The first light blocking layer BM1 and the second light blocking layer BM2 may be formed of an organic film such as an acrylic resin, an epoxy resin, a phenolic resin, a polyamide resin, a polyimide resin, and/or the like. The first light blocking layer BM1 and the second light blocking layer BM2 may include a light-blocking material to prevent or reduce light from a light emitting element LE of a sub-pixel from propagating to an adjacent sub-pixel. For example, the first light blocking layer BM1 and the second light blocking layer BM2 may include an inorganic black pigment such as carbon black and/or an organic black pigment.

The second capping layer CAP2 may be arranged on the first capping layer CAP1 and the light blocking layer BM. The second capping layer CAP2 may be arranged on the side surface and the top surface of the light blocking layer BM. For example, the second capping layer CAP2 may be arranged on the side surface of the first light blocking layer BM1 and the side surface and the top surface of the second first light blocking layer BM2.

The reflective film RF may be arranged between the light blocking layer BM and the first light conversion layer QDL1, between the light blocking layer BM and the second light conversion layer QDL2, and between the light blocking layer BM and the light transmission layer TPL. The reflective film RF may be arranged on the second capping layer CAP2 arranged on the side of the first light blocking layer BM1 and the side of the second light blocking layer BM2. The reflective film RF serves to reflect light that travels in the side direction in the first light conversion layer QDL1, the second light conversion layer QDL2, and the light transmission layer TPL. The first capping layer CAP1, the second capping layer CAP2, and the third capping layer CAP3 may be formed of an inorganic film, such as silicon nitride (SiNₓ, e.g., Si₃N₄), silicon oxide nitride (SiON, e.g., Si₂N₂O), silicon oxide (SiOₓ, e.g., SiO₂), titanium oxide (TiOₓ, e.g., TiO₂), and/or aluminum oxide (AlOₓ, e.g., Al₂O₃). The first light conversion layer QDL1, the second light conversion layer QDL2, and the light transmission layer TPL may be encapsulated by the first capping layer CAP1, the second capping layer CAP2, and the third capping layer CAP3.

The reflective film RF may include a metal material having a suitably high reflectivity, such as aluminum (Al). The thickness of the reflective film RF may be approximately 0.1 μm.

In one or more embodiments, the reflective film RF may include M pairs of first and second layers having different refractive indices (M is an integer greater than or equal to 2) to serve as distributed Bragg reflectors (DBR). In this case, the M first layers and the M second layers may be alternately arranged with each other. The first layer and the second layer may be formed of an inorganic film, such as silicon nitride (SiNₓ, e.g., Si₃N₄), silicon oxide nitride (SiON, e.g., Si₂N₂O), silicon oxide (SiOₓ, e.g., SiO₂), titanium oxide (TiOₓ, e.g., TiO₂), and/or aluminum oxide (AlOₓ, e.g., Al₂O₃).

The third capping layer CAP3 may be arranged on the second capping layer CAP2, the first light conversion layer QDL1, the second light conversion layer QDL2, and the light transmission layer TPL.

The first capping layer CAP1, the second capping layer CAP2, and the third capping layer CAP3 may be formed of an inorganic film, such as silicon nitride (SiNₓ, e.g., Si₃N₄), silicon oxide nitride (SiON, e.g., Si₂N₂O), silicon oxide (SiOₓ, e.g., SiO₂), titanium oxide (TiOₓ, e.g., TiO₂), and/or aluminum oxide (AlOₓ, e.g., Al₂O₃). The first light conversion layer QDL1, the second light conversion layer QDL2, and the lighttransmission layer TPL may be encapsulated by the first capping layer CAP1, the second capping layer CAP2, and the third capping layer CAP3.

A fourth organic layer 213 may be arranged on the second capping layer CAP2. A plurality of color filters CF1, CF2, and CF3 may be arranged on the fourth organic layer 213. The plurality of color filters CF1, CF2, and CF3 may include first color filters CF1, second color filters CF2, and third color filters CF3.

The first color filter CF1 arranged on the first sub-pixel SPX1 may be to transmit first light (light in a red wavelength band) and absorb or block or reduce third light (light in a blue wavelength band). Therefore, the first color filter CF1 may be to transmit the first light (light in the red wavelength band) converted by the first light conversion layer QDL1 among the third light (light in the blue wavelength band) emitted from the light emitting element LE and absorb or block or reduce the third light (light in the blue wavelength band) not converted by the first light conversion layer QDL1. Accordingly, the first sub-pixel SPX1 may be to emit the first light (light in the red wavelength band).

The second color filter CF2 arranged in the second sub-pixel SPX2 may be to transmit the second light (light in the green wavelength band) and absorb or block or reduce the third light (light in the blue wavelength band). Therefore, the second color filter CF2 may be to transmit the second light (light in the green wavelength band) converted by the first light conversion layer QDL1 among the third light (light in the blue wavelength band) emitted from the light emitting element LE and absorb or block or reduce the third light (light in the blue wavelength band) not converted by the first light conversion layer QDL1. Accordingly, the second sub-pixel SPX2 may be to emit the second light (light in the green wavelength band).

The third color filter CF3 arranged in the third sub-pixel SPX3 may be to transmit the third light (light in the blue wavelength band). Therefore, the third color filter CF3 may be to transmit the third light (light in the blue wavelength band) emitted from the light emitting element LE passing through the light transmission layer TPL. Accordingly, the third sub-pixel SPX3 may be to emit the third light (light in the blue wavelength band).

The first color filter CF1, the second color filter CF2, and the third color filter CF3 overlapping in the third direction DR3 may overlap the light blocking layer BM in the third direction DR3.

A fifth organic film 214 for planarization may be arranged on the plurality of color filters CF1, CF2, and CF3.

In some embodiments, the plurality of color filters CF1, CF2, and CF3 may not be provided.

The fourth organic layer 213 and the fifth organic film 214 may be formed from an acrylic resin, an epoxy resin, a phenolic resin, a polyamide resin, a polyimide resin, and/or the like.

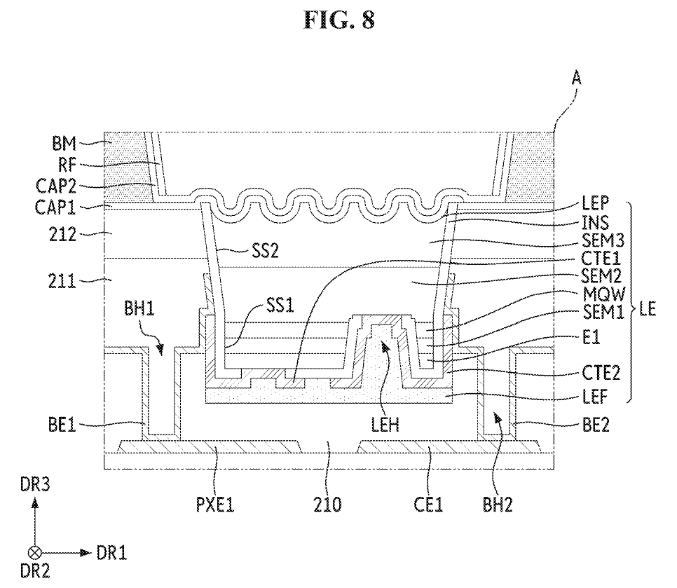

FIG. 8 is a cross-sectional view illustrating another example of area A of FIG. 6 in more detail.

The embodiment of FIG. 8 differs from the embodiment of FIG. 7 in that the shape of the light emitting element LE has a substantially vertical side surface and that the light emitting element LE has a third semiconductor layer SME3. In FIG. 8, descriptions that overlap with the embodiments described with reference to FIGS. 6 and 7 will not be repeated, and differences from the embodiment of FIG. 7 will be mainly described.

Referring to FIG. 8, the light emitting element LE may be patterned through vertical etching and may have a rectangular or square cross-sectional shape in which the width of the top surface and the width of the bottom surface are substantially the same.

The third semiconductor layer SEM3 is arranged on the second semiconductor layer SEM2.

The third semiconductor layer SEM3 is a semiconductor material layer having an n-type or kind dopant lower than a set or predetermined threshold value and may be referred to as an undoped semiconductor layer. For example, the third semiconductor layer SEM3 may be indium aluminum gallium nitride (InAlGaN), gallium nitride (GaN), aluminum gallium nitride (AlGaN), indium gallium nitride (InGaN), aluminum nitride (AlN), and/or indium nitride (InN) having an n-type or kind dopant lower than a set or predetermined threshold value.

The third semiconductor layer SEM3 may be arranged on the second semiconductor layer SEM2. A light extraction pattern LEP may be formed on the top surface of the third semiconductor layer SEM3.

The light extraction patterns LEP may be patterns for increasing the efficiency of light emitted from the top surface of the light emitting element LE. The light extraction patterns LEP may be concave patterns formed into a hemisphere or a semi-ellipse. The light extraction patterns LEP may be concave patterns having a cross-sectional shape of a semicircle or a semi-ellipse.

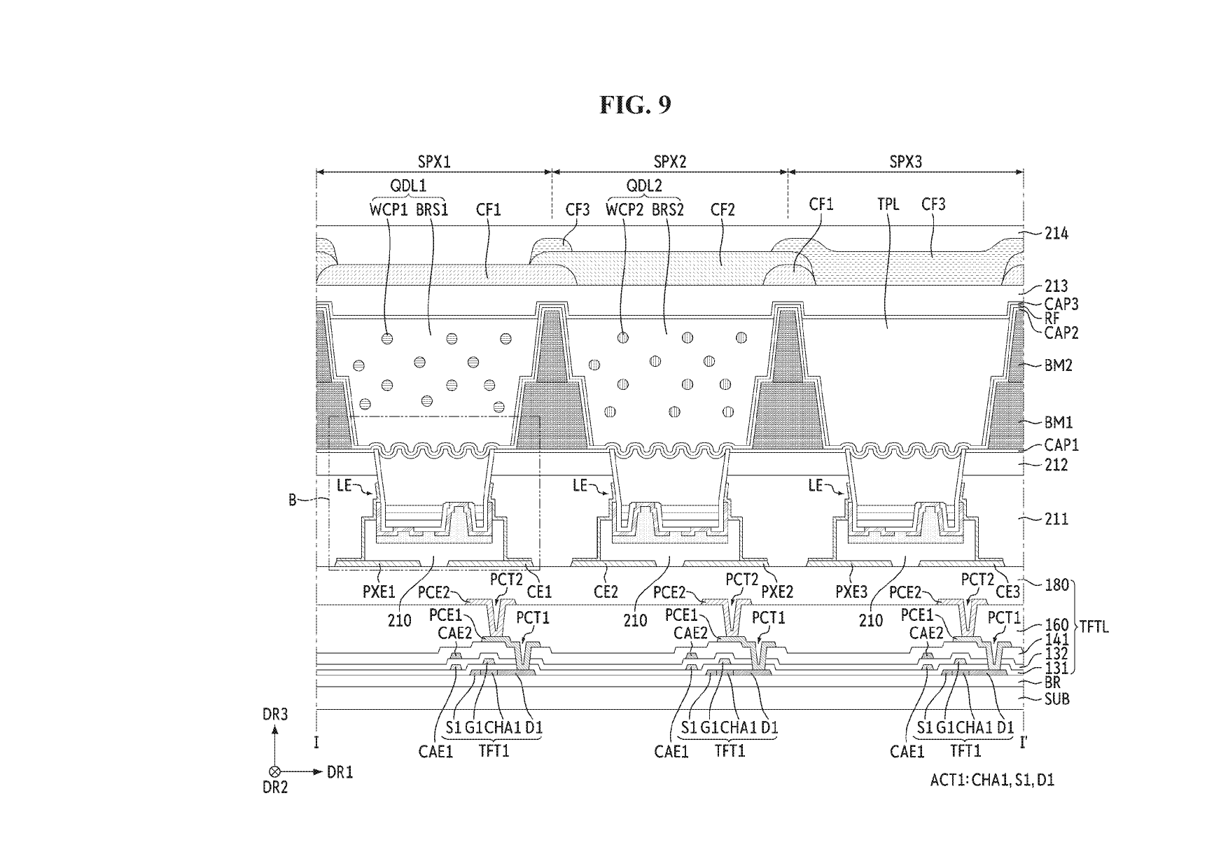

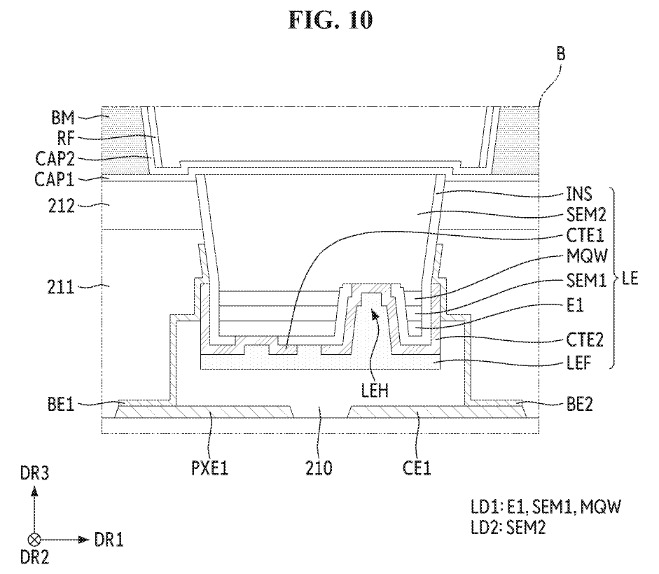

FIG. 9 is a cross-sectional view illustrating another example of the cross-section of the display panel corresponding to the line I-I’ of FIG. 5. FIG. 10 is a cross-sectional view illustrating an example of area B of FIG. 9 in more detail.

The embodiments of FIGS. 9 and 10 differ from the embodiments of FIGS. 6 and 7 in that each of the first organic layers 210 is arranged on a portion of the top surface of the pixel electrodes PXE1, PXE2, and PXE3 and a portion of the top surface of the common electrode CE. In FIGS. 9 and 10, descriptions that overlap with the embodiments of FIGS. 6 and 7 will not be provided, and descriptions will be focused on differences from the embodiments of FIGS. 6 and 7.

Referring to FIGS. 9 and 10, because each of the first organic layers 210 is arranged on a portion of the top surface of each of the pixel electrodes PXE1, PXE2, and PXE3 and a portion of each of the common electrodes CE1, CE2, and CE3, it is not necessary to form a first connection hole BH1 to expose each of the pixel electrodes PXE1, PXE2, and PXE3 and a second connection hole BH2 to expose each of the common electrodes CE1, CE2, and CE3.

Each of the first connection electrodes BE1 may be arranged on a top surface of a pixel electrode PXE1, PXE2, and PXE3 that is not covered by the first organic layer 210. Each of the second connection electrodes BE2 may be arranged on a top surface of a common electrode CE1, CE2, and CE3 that is not covered by the first organic layer 210. Further, each of the first connection electrode BE1 and the second connection electrode BE2 may be arranged on the top surface and at least one side surface of the first organic layer 210.

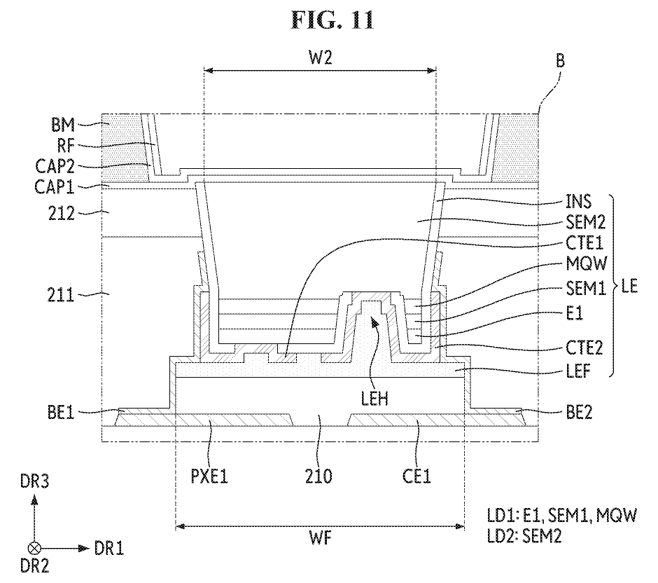

FIG. 11 is a cross-sectional view illustrating another example of area B of FIG. 9 in more detail.

FIG. 11 is different from the embodiment of FIG. 10 in that a first width WF of the element planarization layer LEF is wider than a second width W2 of the second element rod LD2. In FIG. 11, overlapping descriptions with the embodiment of FIG. 10 are omitted, and differences from the embodiment of FIG. 10 are mainly described.

The element planarization layer LEF may protrude outside the first contact electrode CTE1 and the second contact electrode CTE2. The first width WF of the element planarization layer LEF is wider than the second width W2 of the second element rod LD2.

Therefore, the element planarization layer LEF has a relatively large area and may be suitably stably arranged on the first organic layer 210.

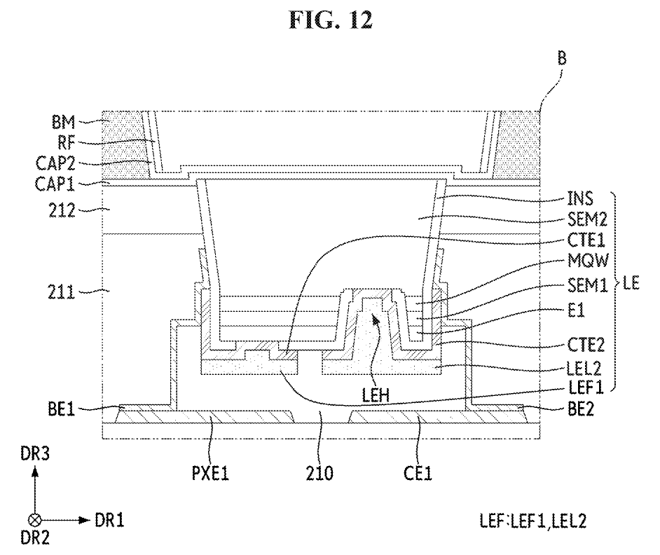

FIG. 12 is a cross-sectional view illustrating another example of area B of FIG. 9 in more detail.

FIG. 12 is different from the embodiment of FIG. 10 in that the element planarization layer LEF is not arranged between the first contact electrode CTE1 and the second contact electrode CTE2. In FIG. 12, descriptions that overlap with the embodiment of FIG. 10 will not be provided, and differences from the embodiment of FIG. 12 will be mainly described.

The element planarization layer LEF may include a first element planarization layer LEF1 and a second element planarization layer LEL2.

The first element planarization layer LEF1 overlaps the first contact electrode CTE1 in the third direction DR3, and the second element planarization layer LEL2 overlaps the second contact electrode CTE2 in the third direction DR3. The element planarization layer LEF does not overlap the space between the first contact electrode CTE1 and the second contact electrode CTE2. The element planarization layer LEF is not arranged between the first contact electrode CTE1 and the second contact electrode CTE2. Therefore, at least a part of one side of the light emitting element LE may be exposed by the element planarization layer LEF. The exposed portion of the light emitting element LE and the first organic layer 210 may be in direct contact. In this way, if (e.g., when) the element planarization layer LEF is not arranged between the first contact electrode CTE1 and the second contact electrode CTE2, the contact area of the light emitting element LE with the first organic layer 210 may be increased.

In one or more embodiments, the exposed portion of the light emitting element LE may be substantially located almost in the center. Therefore, in the step (e.g., act or task) of adhering the light emitting element LE to the first organic layer 210 by pressurizing, the light emitting element LE may be pressurized uniformly (e.g., substantially uniformly) from side to side.

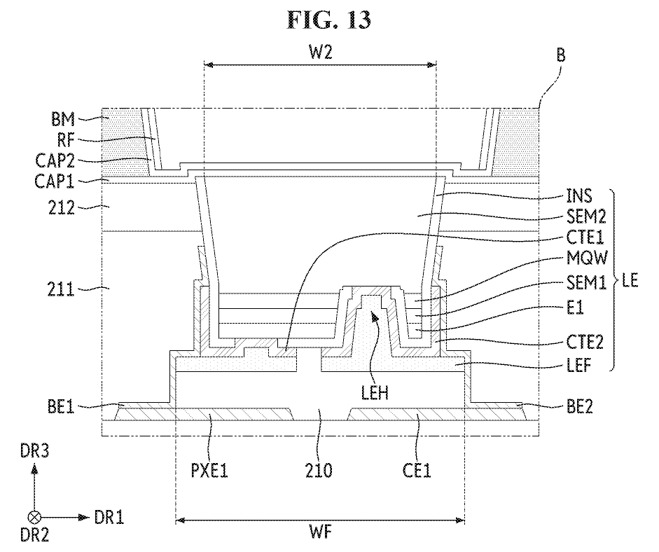

FIG. 13 is a cross-sectional view illustrating another example of area B of FIG. 9 in more detail.

FIG. 13 is different from the embodiment of FIG. 10 in that a first width WF of the element planarization layer LEF is wider than a second width W2 of the second element rod LD2 and the element planarization layer LEF is not arranged between the first contact electrode CTE1 and the second contact electrode CTE2. In FIG. 13, overlapping descriptions with the embodiment of FIG. 10 are omitted and differences from the embodiment of FIG. 10 are mainly described.

The element planarization layer LEF may protrude outside the first contact electrode CTE1 and the second contact electrode CTE2. The first width WF of the element planarization layer LEF is wider than the second width W2 of the second element rod LD2.

The element planarization layer LEF has a relatively large area, so it has the advantage of being suitably stably arranged on the first organic layer 210.

In one or more embodiments, the element planarization layer LEF may include a first element planarization layer LEF1 and a second element planarization layer LEL2.

The first element planarization layer LEF1 may overlap the first contact electrode CTE1 in the third direction DR3 but may protrude outwardly of the first contact electrode CTE1. The second element planarization layer LEL2 may overlap the second contact electrode CTE2 in the third direction DR3 but may protrude outwardly of the second contact electrode CTE2.

The element planarization layer LEF may not overlap between the first contact electrode CTE1 and the second contact electrode CTE2. Therefore, at least a portion of one surface of the light emitting element LE may be exposed by the element planarization layer LEF. The exposed portion of the light emitting element LE and the first organic layer 210 may be in direct contact. The exposed portion of the light emitting element LE may be substantially positioned at the center. Therefore, in the step (e.g., act or task) of adhering the light emitting element LE to the first organic layer 210 by pressurizing, the light emitting element LE may be pressurized uniformly (e.g., substantially uniformly) from side to side.

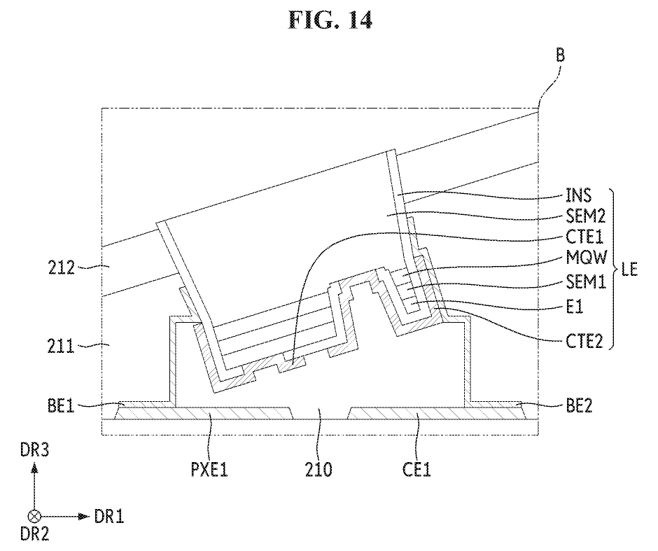

FIG. 14 is a drawing to illustrate an example in which a comparable (e.g., prior art) light emitting element is adhered to the first organic layer without being parallel to the left and right (e.g., without being aligned on the right and left sides).

The light emitting element LE includes a groove LEH, and a step (e.g., height difference) is formed on one surface where the first contact electrode CTE1 and the second contact electrode CTE2 are arranged. In this state, when the light emitting element LE is pressed and adhered to the first organic layer 210 without including the element planarization layer, an uneven distribution of the pressing (e.g., applied) pressure may occur, resulting in an unbalanced placement of the left and right sides. For example, the side of the second contact electrode CTE2 having the groove LEH may receive more pressure than the side of the first contact electrode and may be buried deeper in the first organic layer 210. In this case, the second contact electrode CTE2 may be completely buried in the first organic layer 210, which may cause a miscontact (Mia-contact) between the second contact electrode CTE2 and the common electrode CE1, CE2, and CE3.

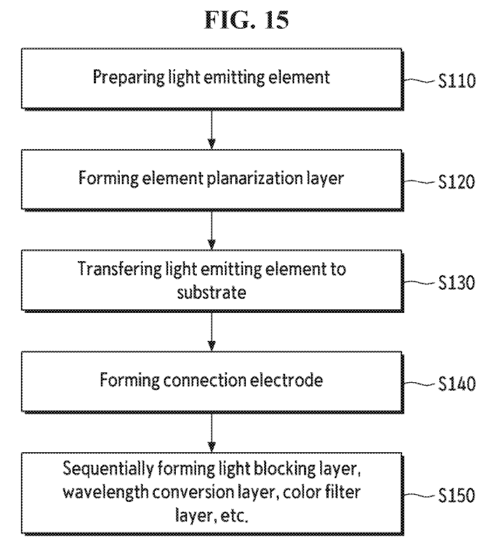

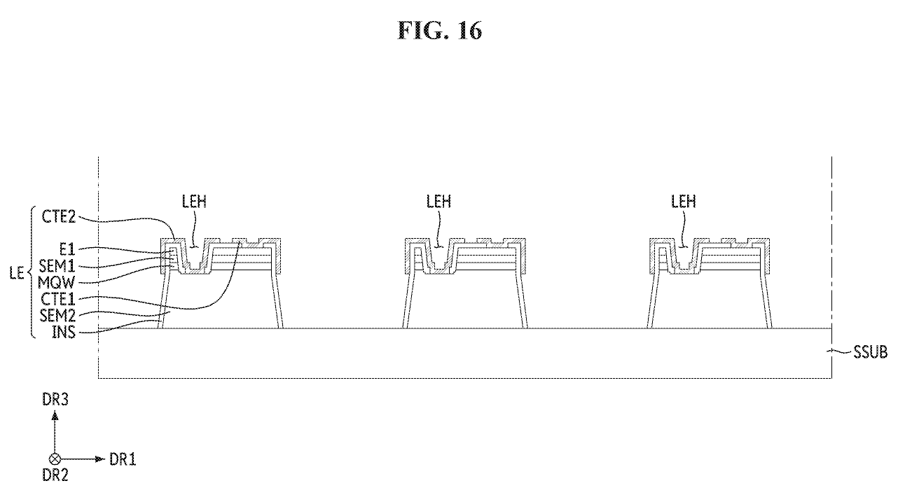

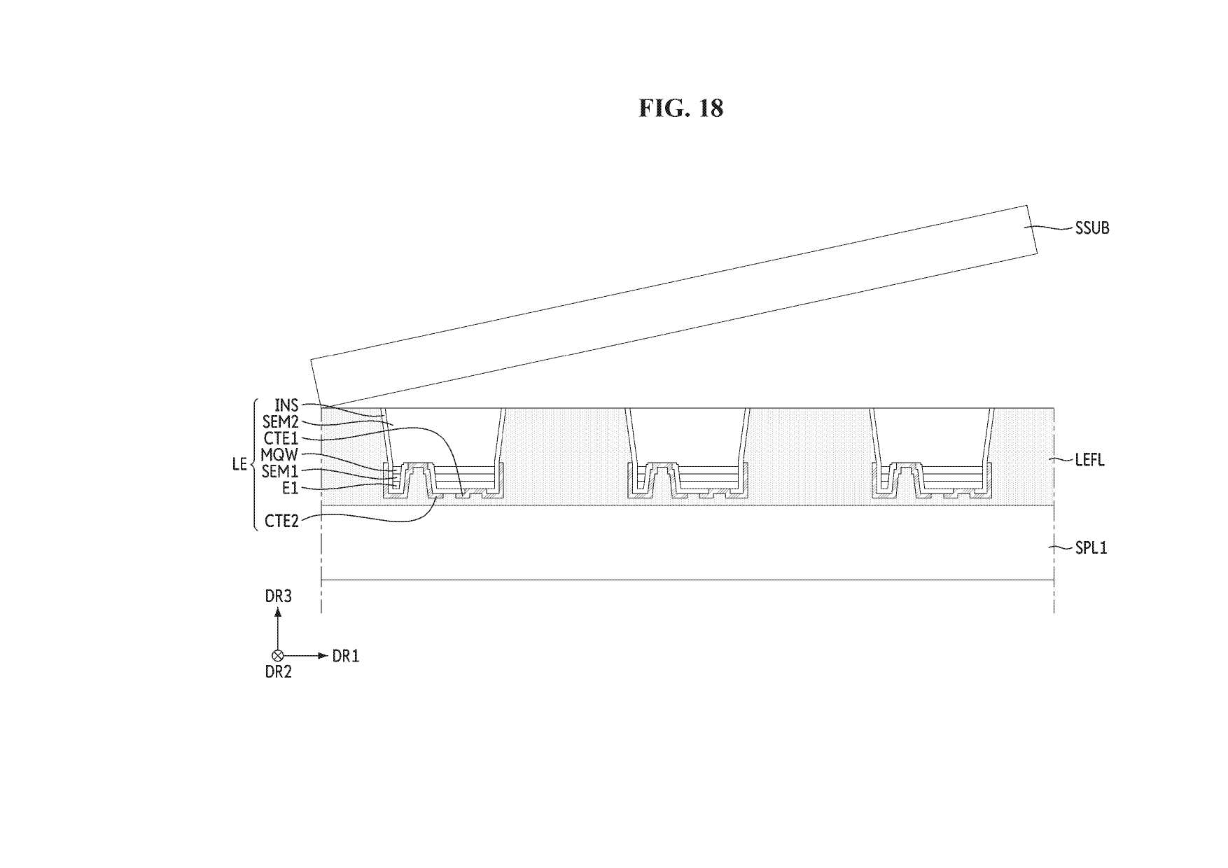

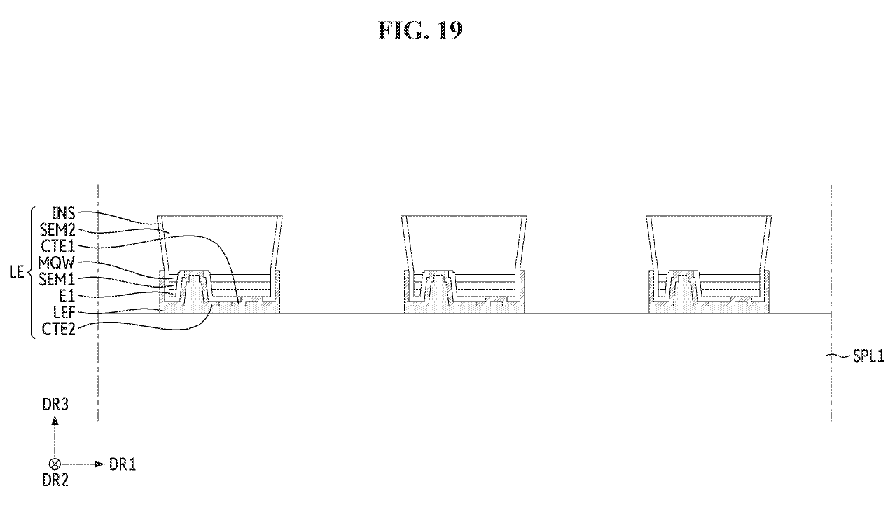

FIG. 15 is a flowchart illustrating a method for manufacturing a display device according to one or more embodiments. FIGS. 16 to 24 are example drawings to illustrate a method for manufacturing a display device according to one or more embodiments.

Hereinafter, a method for manufacturing a display device according to one or more embodiments will be described in more detail by describing FIG. 15 in connection with FIGS. 16 to 24. In FIGS. 16 to 24, cross-sections corresponding to the line I-I’ of FIG. 6 are illustrated for convenience of explanation.

First, as shown in FIG. 16, a light emitting element LE is prepared. (S110 in FIG. 15)

The light emitting element LE is an element grown on a semiconductor substrate SSUB and may be the light emitting element LE described with reference to FIGS. 6 and 7.

The semiconductor substrate SSUB may be a silicon wafer substrate and/or a sapphire substrate.

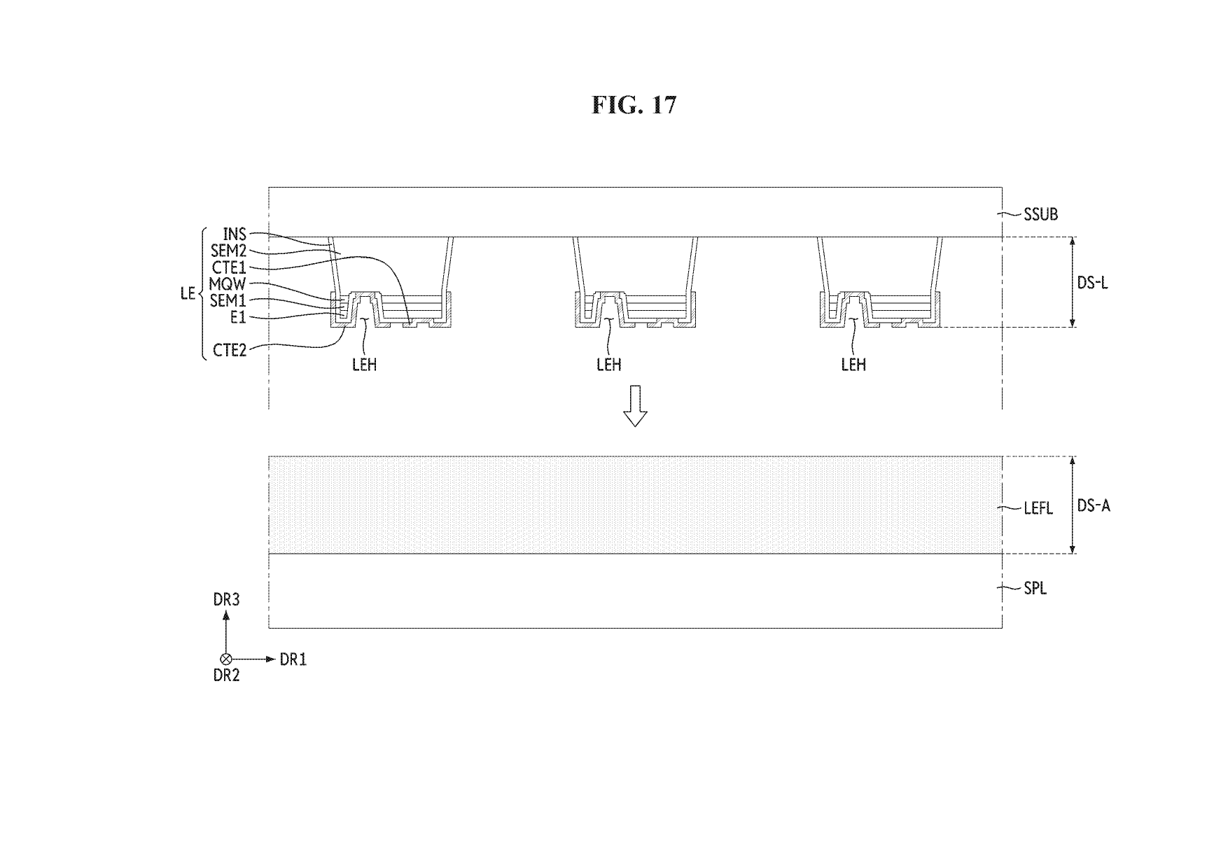

Second, as shown in FIGS. 17 to 19, an element planarization layer LEF may be formed. (S120 in FIG. 15)

The light emitting element LE grown on a semiconductor substrate SSUB may have an adhesive organic layer LEFL arranged on a first relay substrate SPL1.

The first relay substrate SPL1 may be made of a material that is transparent and mechanically stable so that light may pass through it. For example, the first relay substrate SPL may include a transparent polymer such as polyester, polyacrylic, polyepoxy, polyethylene, polystyrene, polyethylene terephthalate, and/or the like.

The adhesive organic layer LEFL may be arranged on the first relay substrate SPL1.

A thickness DS-A of the organic layer LEFL may be thicker than a height DS-L of the light emitting element LE.

The organic layer LEFL may include an adhesive material for bonding the light emitting element LE. The adhesive material may have fluidity. For example, the adhesive material may include urethane acrylate, epoxy acrylate, polyester acrylate, and/or the like. The adhesive material may be a material whose adhesive strength changes when ultraviolet (UV) and/or heat is applied, and thus the adhesive layer may be easily or suitably separated from the light emitting element LE.

After the top surface of the light emitting element LE is arranged to face the organic layer LEFL, the light emitting element LE is pressed so that one side and the side surface of the light emitting element LE are buried in the organic layer LEFL.

Then, a laser (first laser) is irradiated on the semiconductor substrate SSUB to separate the light emitting elements LE from the semiconductor substrate SSUB. The semiconductor substrate SSUB is separated from one side of the plurality of light emitting elements LE, for example, the second semiconductor layer SEM2.

The process of separating the semiconductor substrate SSUB may be carried out by a laser lift off (LLO) process. The laser lift-off process uses a laser, and a KrF excimer laser (248 nm wavelength) may be used as a source. The energy density of the excimer laser is irradiated in the range of about 550mJ/cm² to 950mJ/cm², and the irradiation area (incident area) may be in the range of 50 x 50μm2 to 1 x 1 cm² but the present disclosure is not limited thereto. By irradiating the semiconductor substrate SSUB with the laser, the se miconductor substrate SSUB may be separated from the light emitting element LE.

The organic layer LEFL may be etched to remove the organic layer LEFL arranged on the side of the light emitting element LE. The etching in this process may be dry etching. In this process, each light emitting element LE may be isolated, and an element planarization layer LEF may be formed on one surface of each light emitting element LE.

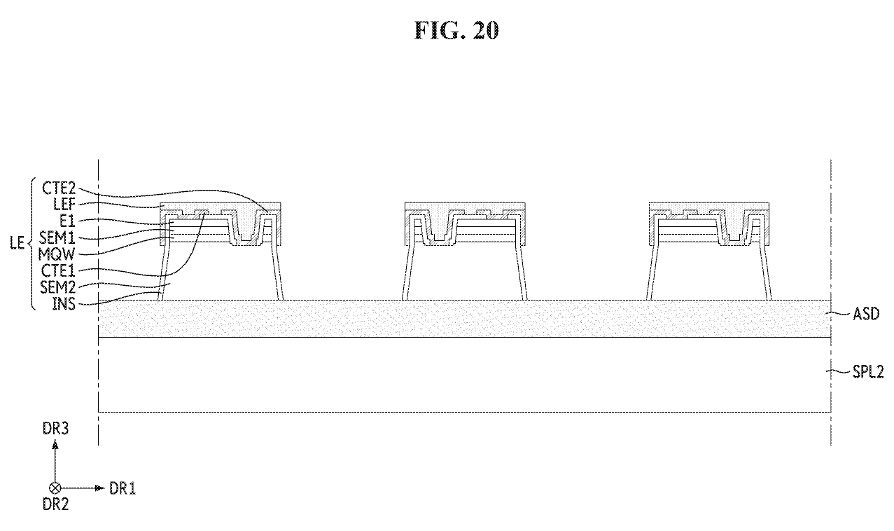

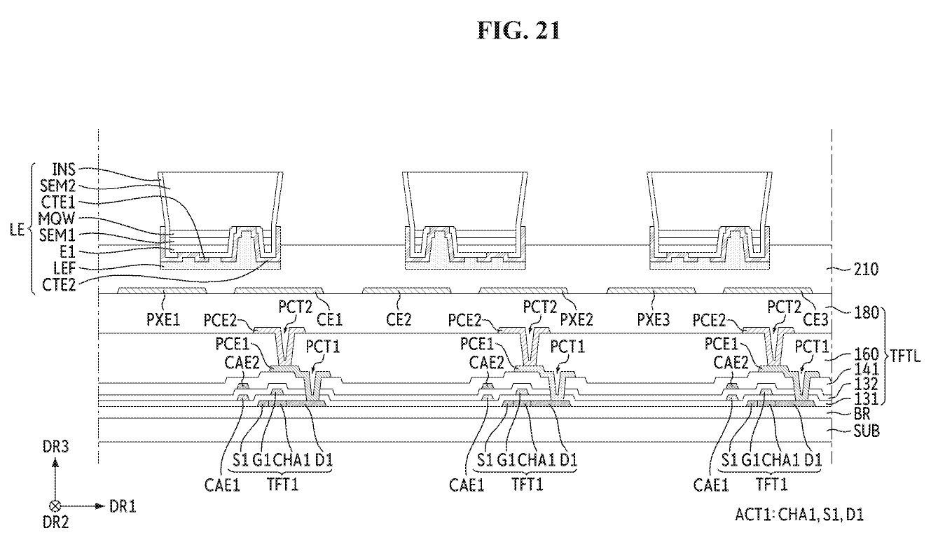

Third, referring to FIGS. 20 and 21, the light emitting element LE may be transferred to the circuit board SUB using the second relay substrate SPL2. (S130 in FIG. 15)

For example, the light emitting elements LE are aligned on the second relay substrate SPL. The second semiconductor layer SEM2 of the light emitting element LE may be arranged so that it faces the second relay substrate SPL2.

The second relay substrate SPL2 may be made of a material that is transparent and mechanically stable so that light may pass through it. For example, the second relay substrate SPL2 may be a glass substrate, but the present disclosure is not limited thereto.

An adhesive material for bonding the light emitting element LE onto the second relay substrate SPL2 may be included. The adhesive material may have fluidity. For example, the adhesive material may be a siloxane-based organic polymer, such as an organosilicon compound such as polydimethylsiloane (PDMS).

A laser is selectively irradiated onto the second relay substrate SPL2. The light emitting element LE irradiated with the laser may be separated from the first relay substrate SPL1 and transferred to the second relay substrate SPL2.

Then, the light emitting element LE may be transferred onto the circuit board SUB. In one or more embodiments, two relay substrates are used but this is not limited thereto.

A first organic layer 210 covering pixel electrodes PXE1, PXE2, and PXE3 and common electrodes CE1, CE2, and CE3 is arranged on the circuit board SUB.

If the first organic layer 210 is a photosensitive organic film such as a photoresist, the first organic layer 210 may be hardened (soft baked) at a first temperature.

The light emitting elements LE may be transferred onto the first organic layer 210. The element planarization layer LEF of each of the light emitting elements LE may be arranged on the first organic layer 210. At this time, the light emitting elements LE may be temporarily fixed (e.g., adhered) by being embedded in the first organic layer 210. The element planarization layer LEF may prevent or reduce the light emitting elements LE from being tilted to either side when they are embedded in the first organic layer 210. Accordingly, a portion of a side surface of the first contact electrode CTE1 of each of the light emitting elements LE and a portion of a side surface of the second contact electrode CTE2 of each of the light emitting elements LE may be arranged on the first organic layer 210. In one or more embodiments, the first organic layer 210 may be arranged on the side surfaces of the element planarization layer LEF of each of the light emitting elements LE. A portion of a side surface of the first contact electrode CTE1 of each of the light emitting elements LE and a portion of a side surface of the second contact electrode CTE2 of each of the light emitting elements LE are not covered by the first organic layer 210. Therefore, a portion of the side surface of the first contact electrode CTE1 of each of the light emitting elements LE and a portion of the side surface of the second contact electrode CTE2 may be exposed by the first organic layer 210.

If the first organic layer 210 is a photosensitive organic film such as a photoresist, after the first organic layer 210 is hardened (soft baked) at a first temperature, at least a portion of each of the plurality of light emitting elements LE is inserted into the first organic layer 210. Then, the first organic layer 210 may be completely hardened at a second temperature higher than the first temperature. The first temperature may be approximately 100 degrees, and the second temperature may be approximately 230 degrees, but the embodiment of the present disclosure is not limited thereto. The process of completely hardening the first organic layer 210 at the second temperature may be performed for approximately 30 minutes.

Then, the second relay substrate SPL2 is removed by a laser lift-off process.

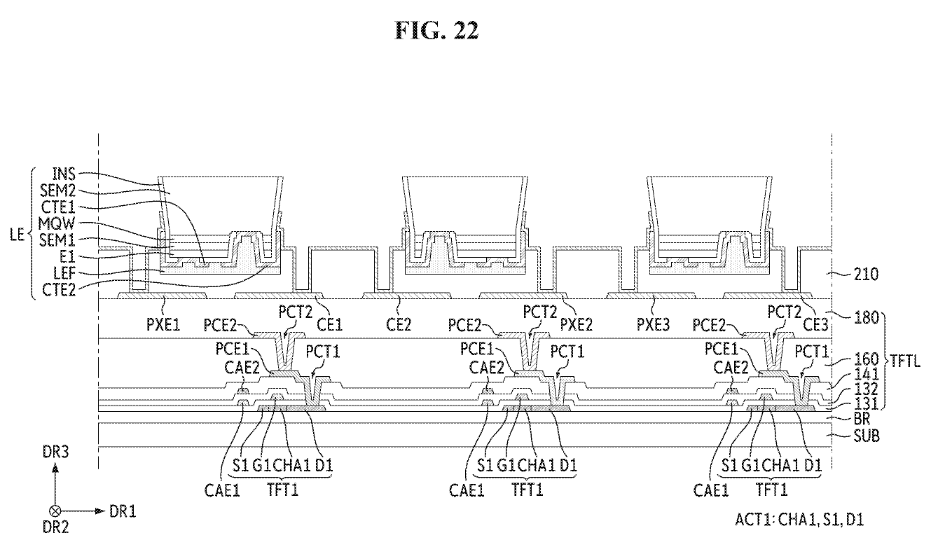

Fourth, referring to FIG. 22, connection electrodes BE1 and BE2 are formed. (S140 in FIG. 15)

A first connection hole BH1 that penetrates the first organic layer 210 and exposes at least a portion of the pixel electrodes PXE1, PXE2, and PXE3, and a second connection hole BH2 that penetrates the first organic layer 210 and exposes at least a portion of the common electrodes CE1, CE2, and CE3 are formed.

Then, first connection electrodes BE1 for connecting the first contact electrode CTE1 of the light emitting element LE arranged on the first organic layer 210 and the pixel electrode PXE exposed by the first connection hole BH1, and second connection electrodes BE2 for connecting the second contact electrode CTE2 and the common electrode PXE exposed by the second connection hole BH2 are formed.

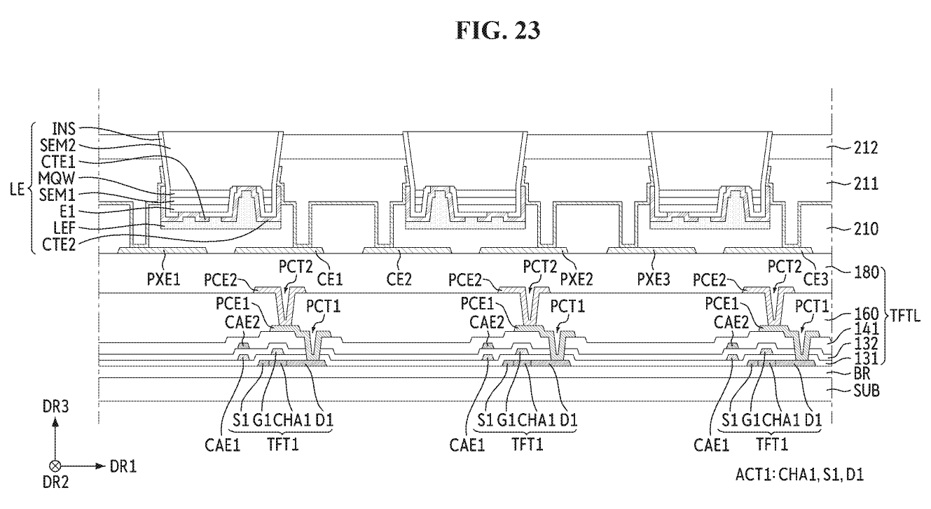

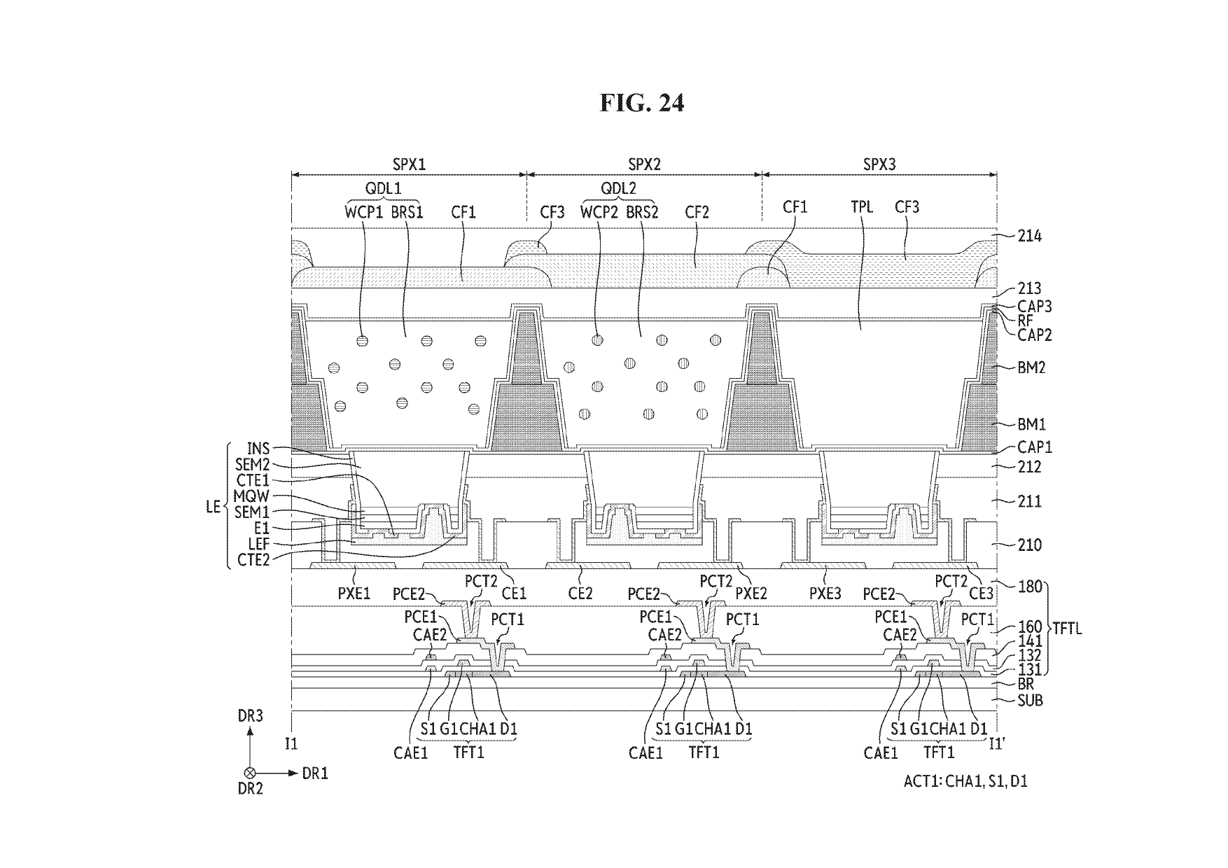

Fifth, referring to FIGS. 23 and 24, a second organic layer 211, a third organic layer 212, a light blocking layer, a wavelength conversion layer, a light transmission layer, and a color filter layer are sequentially formed. (S150 in FIG. 15)

The second organic layer 211 and the third organic layer 212 are formed to fix the light emitting elements LE and to flatten (e.g., substantially flatten or substantially planarize) the steps (e.g., height difference) caused by the light emitting elements LE.

The first capping layer CPL1 is formed on the third organic layer 212 and the light emitting elements LE, and the first light blocking layer BM1 and the second light blocking layer BM2 are formed on the first capping layer CPL1 so as not to overlap with the light emitting elements LE in the third direction DR. Then, a second capping layer CPL2 covering the first light blocking layer BM1, the second light blocking layer BM2, and the first capping layer CPL1 is formed. Then, a reflective film RF covering the second capping layer CPL2 arranged on the first light blocking layer BM1 and the second light blocking layer BM2 is formed.

Then, a first light conversion layer QDL1 is formed on each of the first sub-pixels SPX1, a second light conversion layer QDL2 is formed on each of the second sub-pixels SPX2, and a light transmission layer TPL is formed on each of the third sub-pixels SPX3. Then, a third capping layer CPL3 covering the first light conversion layers QDL1, the second light conversion layers QDL2, and the light transmission layers TPL is formed. Then, a fourth organic layer 213 is formed on the third capping layer CPLb.

Then, a first color filter CF1 is formed on the fourth organic layer 213 overlapping the first light conversion layers QDL1 in the third direction DR3, a second color filter CF2 is formed overlapping the second light conversion layers QDL2 in the third direction DR3, and a third color filter CF3 is formed overlapping the light transmission layers TPL in the third direction DR3. The first color filter CF1, the second color filter CF2, and the third color filter CF3 may all be formed in the region overlapping the first light blocking layer BM1 and the second light blocking layer BM2 in the third direction DR3.

Then, a fifth organic film 214 is formed on the first color filter CF1, the second color filter CF2, and the third color filter CF3.

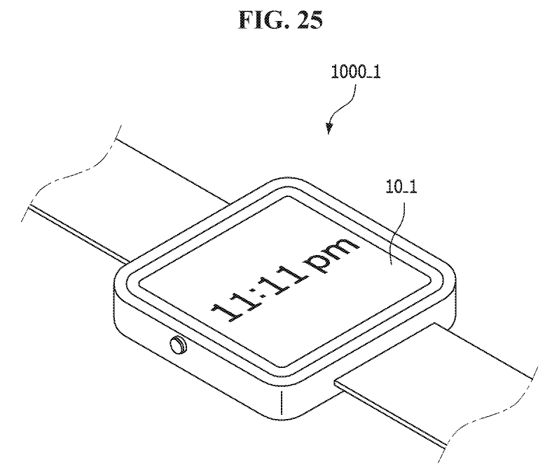

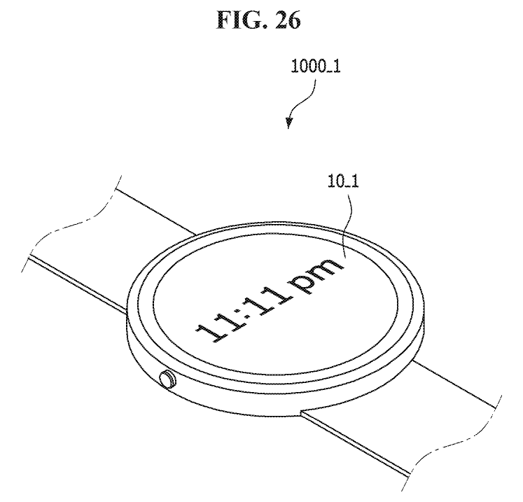

FIGS. 25 and 26 are example drawings illustrating a smart watch including a display device according to one or more embodiments.

Referring to FIGS. 25 and 26, a display device 10_1 according to one or more embodiments may be applied to a smart watch 1000_1, which is one of smart devices.

The flat shape of the display device 10_1 may be a square or a circle but the present disclosure is not limited thereto and may be modified in one or more suitable ways, such as being an oval.

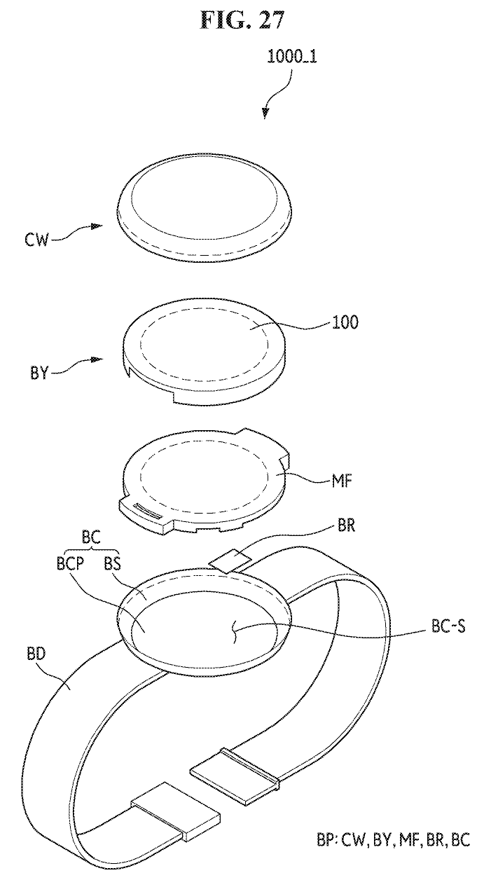

FIG. 27 is an exploded perspective view of a smart watch including a display device according to one or more embodiments.

Referring to FIG. 27, the smart watch 1000_1 may include a main body unit BP and a wearable portion BD.

The main body unit BP may include a display panel 100 on which an image is displayed, a cover window CW provided on the display panel 100, a bottom cover BC provided under the display panel 100, a middle frame MF provided between the cover window CW and the bottom cover BC, and a battery BR provided between the middle frame MF and the bottom cover BC. In addition to the battery BR, a main processor controlling the smart watch 1000_1, a communication chipset for wirelessly communicating with the outside, and a circuit board in which memory, and/or the like are mounted may be additionally arranged between the middle frame MF and the bottom cover BC.

The main body unit BP may sequentially include a bottom cover BC, a battery BR, a middle frame MF, a display panel 100, and a cover window CW.

The cover window CW is arranged on the upper portion of the display panel 100 to protect the display panel 100 and to transmit light emitted from the display panel 100. As described above, the cover window CW may include a light-blocking portion to block or reduce a portion of the light emitted from the display panel 100. The cover window CW may be made of a transparent plastic material, a glass material, and/or a reinforced glass material.

The cover window CW may be arranged to overlap the display panel 10 and cover the front of the display panel 100. The cover window CW may have a shape similar to that of the display panel 10 in terms of a plane (e.g., a similar planar shape), but its size may be larger than that of the display panel 100. For example, the cover window CW may protrude outward from the display panel 100. The plane shape of the cover window CW may be the same as that of the main body unit BP. For example, the planar shape of the cover window CW may be circular (or substantially circular) but the present disclosure is not limited thereto, and the cover window CW may have one or more suitable shapes, for example, a polygon such as a square and/or an oval.

The middle frame MF is a joining member for joining the cover window CW and the bottom cover BC and may be arranged between the cover window CW and the bottom cover BC. For example, the middle frame MF may include a bracket.

The bottom cover BC is a housing arranged under the display panel 10.

The bottom cover BC may include a central cover portion BCP and a peripheral portion BS arranged around the central cover portion BCP.

The central cover portion BCP is located at the center of the bottom cover BC and may be substantially flat.

The peripheral portion BS may be arranged to surround the central cover portion BCP. The peripheral portion BS may be a portion that is bent and curved from the central cover portion BCP. The peripheral portion BS may be bent from the edge of the central cover portion BCP. In some embodiments, the peripheral portion BS may include a curved surface having a set or predetermined curvature, and the other portion may be flat or substantially flat. The degree (or angle) at which the peripheral portion BS is bent from the central cover portion BCP may be an obtuse angle, but the present disclosure is not limited thereto, and may also be a right angle or an acute angle.

A storage space BC-S may be formed by the central cover portion BCP and the peripheral portion BS. A battery BR may be placed in the storage space BC-S.

The battery BR may be connected to a circuit board on which a main processor and/or the like is mounted. The display device 10_1 may be electrically connected to the circuit board to receive digital video signals, timing signals, power, and/or the like.

The bottom cover BC is placed on the outermost rear surface of the electronic device and may include at least one selected from among a plastic material, a metal material, and a glass material, and may include a color coating layer. For example, the bottom cover BC according to one or more embodiments may be a flat (or substantially flat) glass having a transparent, translucent, or opaque color coating layer.

The bottom cover BC according to one or more other embodiments may have the same shape as the cover window CW and may include a glass material having a color coating layer. For example, the bottom cover BC may have a structure substantially symmetrical to the cover window CW with a middle frame MF in between and may include a transparent, translucent, or opaque color coating layer.

The wearing portion BD is a portion for fixing the main body unit BP to the user’s wrist, for example, and may be one selected from among a strap, a chain, and a bracelet.

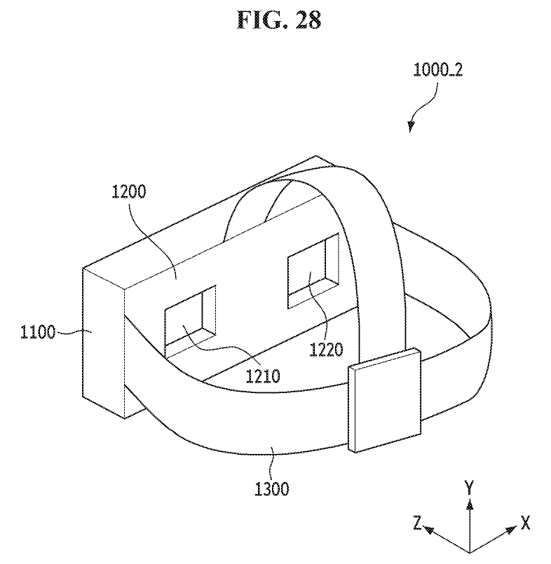

FIG. 28 is an example view of a virtual reality (VR) device including a display device according to one or more embodiments.

Referring to FIG. 28, a head mounted display device 1000_2 according to one or more embodiments may include a display device housing 1100, a housing cover 1200, a first eyepiece 1210, a second eyepiece 1220, and head mounted band 1300.

The display device housing 1100 houses a display device. A head mounted display device 1000_2 according to one or more embodiments may further include a first optical member provided between the display device and the first eyepiece 1210.

The housing cover 1200 is placed to cover an open surface of the display device housing 1100. The housing cover 1200 may include the first eyepiece 1210 on which a user’s left eye is placed and the second eyepiece 1220 on which the user’s right eye is placed. Although the first eyepiece 1210 and the second eyepiece 1220 are provided separately (e.g., spaced apart) in FIG. 28, the present disclosure is not limited thereto. The first eyepiece 1210 and the second eyepiece 1220 may also be combined into one.

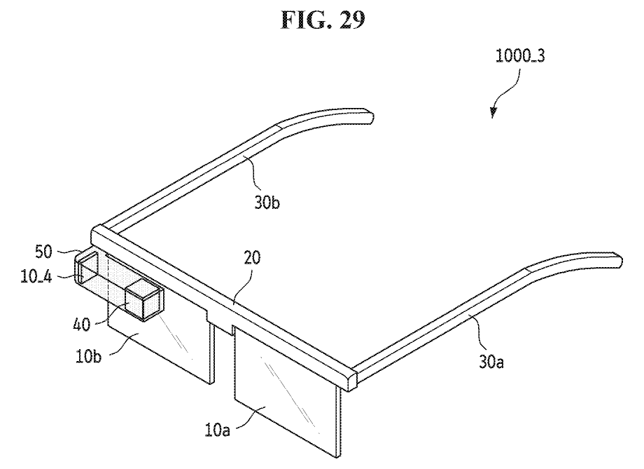

The head mounted band 1300 fixes the display device housing 1100 to a user’s head so that the first eyepiece 1210 and the second eyepiece 1220 of the housing cover 1200 are kept placed on the user’s left and right eyes, respectively. When the display device housing 1200 is implemented to be lightweight and small, the head mounted display device 1000_2 may include an eyeglass frame as illustrated in FIG. 29 instead of the head mounted band 1300 .

The display device housing 1100 houses the display device. In one or more embodiments, the head mounted display device 1000_2 may further include a battery for supplying power, an external memory slot for accommodating an external memory, and an external connection port and a wireless communication module for receiving an image source. The external connection port may be a universe serial bus (USB) terminal, a display port, and/or a high-definition multimedia interface (HDMI) terminal, and the wireless communication module may be a 5G communication module, a 4G communication module, a Wi-Fi module, and/or a Bluetooth module.

FIG. 29 is an example view of a VR device including a display device according to one or more embodiments. FIG. 29 illustrates a VR device 1000_3 to which a display device 10_4 according to one or more embodiments has been applied.

Referring to FIG. 29, the VR device 1000_3 according to one or more embodiments may be a device in the form of glasses. The VR device 1000_3 according to the embodiments may include the display device 10_4, a left lens 10a, a right lens 10b, a support frame 20, eyeglass frame legs 30a and 30b, a reflective member 40, and a display device housing 50.

In FIG. 29, a case where the VR device 1000_3 is a glasses-type or kind display device including the eyeglass frame legs 30a and 30b is illustrated as an example. For example, the VR device 1000_3 according to the embodiments is not limited to the one illustrated in FIG. 29 and can be applied in one or more suitable forms to one or more suitable other electronic devices.

The display device housing 50 may include the display device 10_4 and the reflective member 40. An image displayed on the display device 10_4 may be reflected by the reflective member 40 and provided to a user’s right eye through the right lens 10b. Accordingly, the user may view a VR image displayed on the display device 10_4 through the right eye.

Although the display device housing 50 is provided at a right end of the support frame 20 in FIG. 29, the present disclosure is not limited thereto. For example, the display device housing 50 may also be provided at a left end of the support frame 20. In this case, an image displayed on the display device 10_4 may be reflected by the reflective member 40 and provided to the user’s left eye through the left lens 10a. Accordingly, the user may view a VR image displayed on the display device 10_4 through the left eye. In one or more embodiments, the display device housing 50 may be provided at both (e.g., simultaneously) the right end and the left end of the support frame 20. In this case, the user may view a VR image displayed on the display device 10_4 through both (e.g., simultaneously) the left eye and the right eye.

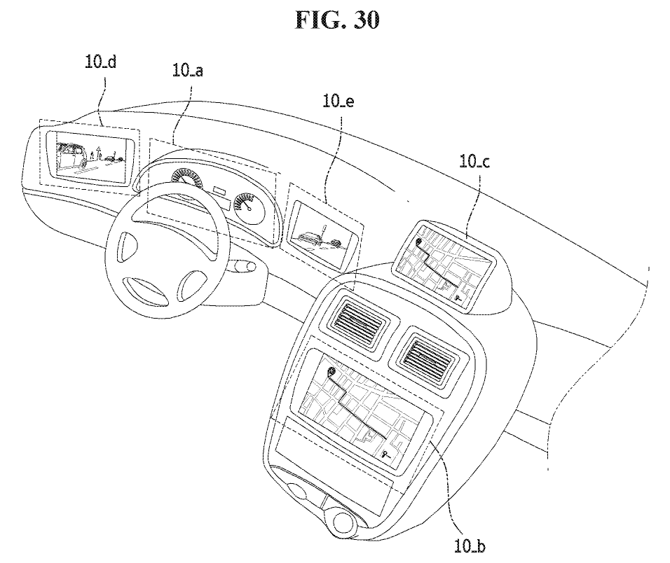

FIG. 30 is an example view illustrating a vehicle instrument cluster and center fascia including display devices according to one or more embodiments. FIG. 23 illustrates a vehicle to which display devices 10_a through 10_e according to one or more embodiments have been applied.

Referring to FIG. 30, the display devices 10_a through 10_c according to the embodiments may be applied to an instrument cluster of the vehicle, a center fascia of the vehicle, and/or a center information display (CID) provided on a dashboard of the vehicle. In one or more embodiments, the display devices 10_d and 10_e according to the embodiments may be applied to room mirror displays that replace side mirrors of the vehicle.

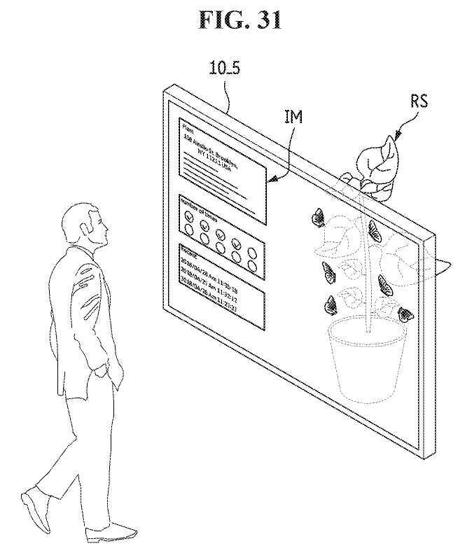

FIG. 31 is an example view of a transparent display device including a display device according to one or more embodiments.

Referring to FIG. 31, a display device 10_5 according to one or more embodiments may be applied to a transparent display device. The transparent display device may be to transmit light while displaying an image IM. Therefore, a user located in front of the transparent display device can view not only the image IM displayed on the display device 10_5 but also view an object RS or the background located behind the transparent display device. When the display device 10_5 is applied to the transparent display device, a substrate of the display device 10_5 may include a light transmitting portion that can transmit light and/or may be made of a material that can transmit light.

It should be understood, however, that the aspects and features of embodiments of the present disclosure are not restricted to the one set forth herein. The above and other aspects of the present disclosure will become more apparent to one of ordinary skill in the art to which the present disclosure pertains by referencing the claims, with equivalents thereof to be included therein.

What is claimed is:

1. A display device comprising:
a substrate;
a pixel electrode and a common electrode spaced apart from each other on the substrate;
a first organic layer covering at least a portion of the pixel electrode and the common electrode; and
a light emitting element on the first organic layer, the light emitting element comprising an element planarization layer, a plurality of semiconductor layers, a first contact electrode, and a second contact electrode,
wherein the element planarization layer covers one surface of the first contact electrode and the second contact electrode, and planarizes a step caused by the first contact electrode and the second contact electrode,
wherein the first organic layer covers one surface and a side surface of the element planarization layer.

2. The display device of claim 1, wherein the first contact electrode and the second contact electrode are respectively arranged on one side and a side surface of the light emitting element and are spaced apart from a top surface of the light emitting element.

3. The display device of claim 2, further comprising a first connection electrode connecting the pixel electrode and the first contact electrode, and a second connection electrode connecting the common electrode and the second contact electrode.

4. The display device of claim 3, wherein the first contact electrode is in direct contact with the first connection electrode at a side surface of the plurality of semiconductor layers, and the second contact electrode is in direct contact with the second connection electrode at a side surface of the plurality of semiconductor layers.

5. The display device of claim 1, wherein the light emitting element further comprises:
a conductive layer on the element planarization layer; and
a protective film on one surface and side surfaces of the conductive layer and side surfaces of the plurality of semiconductor layers,
wherein the first contact electrode is on the protective film and is connected to the conductive layer exposed without being covered by the protective film,
wherein the second contact electrode is on the protective film and is in a hole penetrating the conductive layer and a portion of the plurality of semiconductor layers.

6. The display device of claim 5, wherein the element planarization layer is filled in the hole.

7. The display device of claim 6, wherein the element planarization layer is made of an insulating organic material.

8. The display device of claim 7, wherein the element planarization layer covers entire surface of one surface on which the first contact electrode and the second contact electrode are arranged.

9. The display device of claim 7, wherein the side surface of the element planarization layer is aligned with the side surface of each of the first contact electrode and the second contact electrode.

10. The display device of claim 7, wherein the side surface of the element planarization layer protrudes further than the side surfaces of the first contact electrode and the second contact electrode.

11. The display device of claim 7, wherein the element planarization layer is not arranged between the first contact electrode and the second contact electrode.

12. The display device of claim 11, wherein the first organic layer is in contact with one surface of the protective film between the first contact electrode and the second contact electrode.

13. The display device of claim 7, wherein the light emitting element is divided into a first element rod having a first inclination angle on a side surface, and
a second element rod arranged on the first element rod and having a second inclination angle on the side surface,
wherein the second inclination angle is smaller than the first inclination angle.

14. The display device of claim 13, wherein the first element rod comprises the conductive layer, a first semiconductor layer, and an active layer,
wherein the first contact electrode and the second contact electrode are on a side surface of the first element rod.

15. A method for manufacturing a display device, the method comprising:
forming an element planarization layer on one surface of a light emitting element arranged on a first substrate;
forming an organic layer covering at least a portion of a pixel electrode and a common electrode arranged on a second substrate;
aligning the element planarization layer facing the organic layer in each of the light emitting elements, and then transferring the light emitting elements onto the organic layer; and
forming a first connection electrode connecting a first contact electrode of the light emitting element to the pixel electrode and a second connection electrode connecting a second contact electrode of the light emitting element to the common electrode.

16. The method of claim 15, wherein the forming the element planarization layer comprises,
preparing a light emitting element having the first contact electrode and the second contact electrode spaced apart from each other on one side;
preparing a first relay substrate having an organic layer having adhesion arranged on a top surface of the first relay substrate;
transferring the light emitting element onto the organic layer and removing the first relay substrate; and
dry etching the organic layer to remove the organic layer arranged on the side of the light emitting element, thereby forming the element planarization layer on one side of the light emitting element.

17. The method of claim 15, wherein in the transferring the light emitting elements onto the organic layer,
a portion of a side surface of the first contact electrode and a portion of a side surface of the second contact electrode of the light emitting elements are embedded in the organic layer, and a remaining portion of the side surface of the first contact electrode and a remaining portion of the side surface of the second contact electrode are not covered by the organic layer.

18. The method of claim 17, wherein the first connection electrode is connected to a remaining portion of the side surface of the first contact electrode, and the second connection electrode is connected to a remaining portion of the side surface of the second contact electrode.

19. An electronic device comprising:
a display panel;
a window on the display panel; and
a bottom cover below the display panel,
wherein the display panel comprises:
a substrate;
a pixel electrode and a common electrode spaced apart from each other on the substrate;
a first organic layer covering at least a portion of the pixel electrode and the common electrode; and
a light emitting element on the first organic layer, the light emitting element comprising an element planarization layer, a plurality of semiconductor layers, a first contact electrode, and a second contact electrode,
wherein the element planarization layer covers one surface of the first contact electrode and the second contact electrode, and planarizes a step caused by the first contact electrode and the second contact electrode,
wherein the first organic layer covers one surface and a side surface of the element planarization layer.

20. The electronic device of claim 19, further comprising,
a battery arranged in a space of the bottom cover and configured to supply power to the display panel; and
a middle frame arranged between the window and the bottom cover.
